(19) United States
(12) Patent Application Publication
(10) Pub. No.: US 2012/0205543 A1
(43) Pub. Date: Aug. 16, 2012

(54) RADIOLOGICAL IMAGE DETECTION APPARATUS AND METHOD OF MANUFACTURING THE SAME

(75) Inventors: Haruyasu NAKATSUGAWA, Kanagawa (JP); Yasuhisa KANEKO, Kanagawa (JP); Naoto IWAKIRI, Kanagawa (JP)

(73) Assignee: FUJIFILM CORPORATION, Tokyo (JP)

(21) Appl. No.: 13/372,318

(22) Filed: Feb. 13, 2012

(30) Foreign Application Priority Data
Feb. 14, 2011 (JP) 2011-028973

(51) Int. Cl. G01T 1/202; H01L 31/18; G01T 1/20

(52) U.S. Cl. 250/366; 438/65; 257/E31.129

(57) ABSTRACT

A radiological image detection apparatus includes: a first scintillator and a second scintillator that emit fluorescent lights in response to irradiation of radiation; and a first photodetector and a second photodetector that detect the fluorescent lights; in which the first photodetector, the first scintillator, the second photodetector, and the second scintillator are arranged in order from a radiation incident side, and a high activator density region in which an activator density is relatively higher than an average activator density in a concerned scintillator is provided to at least one of the first scintillator located in vicinity of the first photodetector and the second scintillator located in vicinity of the second photodetector.

### CROSS-REFERENCE TO RELATED APPLICATIONS

This application is based on and claims priority under 35 USC 119 from Japanese Patent Application No. 2011-028973 filed on Feb. 14, 2011; the entire content of which is incorporated herein by reference.

### BACKGROUND

1. Technical Field

The present invention relates to a radiological image detection apparatus used in the medical X-ray imaging system etc., and a method of manufacturing the same.

2. Related Art

In recent years, DR (Digital Radiography) using the X-ray image detection apparatus such as FPD (Flat Panel Detector) that converts an X-ray image into digital data, or the like is already put to practical use. In contrast to the former CR (Computed Radiography) system using the imaging plate formed of the stimulative phosphor (accumulative phosphor), this X-ray image detection apparatus has such a merit that the picked-up image can be checked on the spot, and thus its spread is proceeding apace.

Various systems have been proposed for an X-ray image detection apparatus. As one of them, the indirect conversion system, which converts the X rays into the visible lights once by the scintillator such as CsI:Tl, GOS (Gd₂O₂S:Tb), or the like, and then converts the visible lights into the electric charges by the semiconductor layers and stores such electric charges, has been known (see Patent Document 1 (JP-A-2007-163467), Patent Document 2 (JP-A-2008-51793) and Patent Document 3 (JP-A-2011-17683), for example).

In the X-ray image detection apparatus, in many cases it is preferable that the X-ray exposure should be set low when this detecting device is used for the X-ray radiography of a living body, for example. Therefore, the scintillator whose sensitivity to the X-rays is high and whose amount of luminescence is large is demanded. In Patent Document 1, an amount of luminescence is enhanced by providing the scintillator on both sides of the photodetector respectively to put it between them.

Also, in Patent Document 2, an amount of luminescence is enhanced by adding the activator to the base material of the fluorescent material. In Patent Document 2, it is set forth that, in the X-ray image detection apparatus which includes the photodetector and the scintillator and in which the X-rays are incident on the scintillator from the opposite side to the photodetector, the activator density in the region of the scintillator on the X-ray incident side should be enhanced.

Also, in Patent Document 3, an amount of luminescence is enhanced by setting the region of the scintillator, which is located in vicinity to the photodetector, as the main luminescence region S in the situation that the scintillator is irradiated with the X-rays from the photodetector side.

Here, it may be considered that an activator density on the X-ray incident side should be increased, as set forth in Patent Document 2, and also the photodetector side should be set as the main luminescence region, as set forth in Patent Document 3. In this manner, when an activator density is enhanced in vicinity to the photodetector on the X-ray incident side, the effect of increasing amount of luminescence and improving MTF (Modulation Transfer Function) can be achieved to a certain extent. However, when such main luminescence region of the scintillator is examined in detail, the following problems still remain. That is, an increase of an activator density poses clearly the technical problems mentioned hereunder.

The crystallinity of the part of the main luminescence region, which is located in vicinity of the photodetector, is disordered due to the increase of the activator density, and accordingly the degradation of MTF is caused. In particular, when an activator density is enhanced in the initial phase of the vapor deposition of the scintillator, such enhancement has a tremendous adverse influence on the crystal growth of the scintillator, and the crystallinity is disordered. Therefore, the lights are diffused between the columnar crystals, and thus degradation of MTF is caused.

Also, the absorption of lights in the scintillator is increased due to an increase of the activator density. Here, as shown in FIG. 17, such a comparative case is considered that an activator density is enhanced in the situation that the part of a scintillator 91 located on the X-ray incident side is set as the main luminescence region S. As shown in FIG. 18A and FIG. 18B, in a part P2 that is positioned away from a photodetector 92 (FIG. 17) in the main luminescence region S, an amount of luminescence incident on the photodetector 92 is small, and a light emitting condition is spread, and thus blurriness of the image is caused (MTF is worsened). As a result, even though such a configuration is employed that, as shown in FIG. 17, the scintillator 91 is irradiated with the X rays from the photodetector 92 side, a further increase of an amount of luminescence and a further improvement in MTF cannot be expected unless such problems are solved.

### SUMMARY

An illustrative aspect of invention is to provide a radiological image detection apparatus capable of achieving a further increase of an amount of luminescence and a further improvement in MTF, and a method of manufacturing the same.

According to an aspect of the invention, a radiological image detection apparatus, includes: a first scintillator and a second scintillator that emit fluorescent lights in response to irradiation of radiation; and a first photodetector and a second photodetector that detect the fluorescent lights; in which the first photodetector, the first scintillator, the second photodetector, and the second scintillator are arranged in order from a radiation incident side, and a high activator density region in which an activator density is relatively higher than an average activator density in a concerned scintillator is provided to at least one of the first scintillator located in vicinity of the first photodetector and the second scintillator located in vicinity of the second photodetector.

According to another aspect of the invention, a method of manufacturing the radiological image detection apparatus includes: a second photodetector forming step of forming the second photodetector on a substrate; and a substrate peeling step of peeling the substrate from the second photodetector.

With the configuration and process, in the radiological image detection apparatus in which the first photodetector, the first scintillator, the second photodetector, and the second scintillator are arranged in order from the radiation incident side, a further increase of an amount of luminescence and a further improvement in MTF can be achieved.

### BRIEF DESCRIPTION OF THE DRAWINGS

FIG. 1 is a side sectional view showing schematically a schematic configuration of an X-ray image detection apparatus.

FIG. 2 is a side sectional view showing schematically schematic configurations of photodetectors.

FIG. 3 is a plan view showing schematically a configuration of the photodetector.

FIG. 4 is a side sectional view showing schematically a crystal structure of a scintillator.

FIG. 5 is an electron microscope photograph showing a columnar crystal section (SEM image).

FIG. 6 is an electron microscope photograph showing a non-columnar crystal section (SEM image).

FIG. 7A and FIG. 7B are views showing activator densities and amounts of luminescence of first and second scintillators.

FIG. 8A and FIG. 8B are views showing activator densities and amounts of luminescence of first and second scintillators.

FIG. 9A and FIG. 9B are views showing activator densities and amounts of luminescence of first and second scintillators.

FIG. 10A and FIG. 10B are views showing activator densities and amounts of luminescence of first and second scintillators.

FIG. 11A and FIG. 11B are views showing activator densities and amounts of luminescence of first and second scintillators.

FIG. 12 is a side sectional view showing schematically a schematic configuration of an X-ray image detection apparatus.

FIG. 13 is a side sectional view showing schematically a schematic configuration of an X-ray image detection apparatus.

FIG. 14 is a side sectional view showing schematically a schematic configuration of an X-ray image detection apparatus.

FIG. 15 is a schematic view showing a variation of the photodetector.

FIG. 16 is a schematic view showing another variation of the photodetector.

FIG. 17 is a side sectional view showing schematically a schematic configuration of an X-ray image detection apparatus.

FIG. 18A and FIG. 18B view showing an activator density and an amount of luminescence of the scintillator.

### DETAILED DESCRIPTION

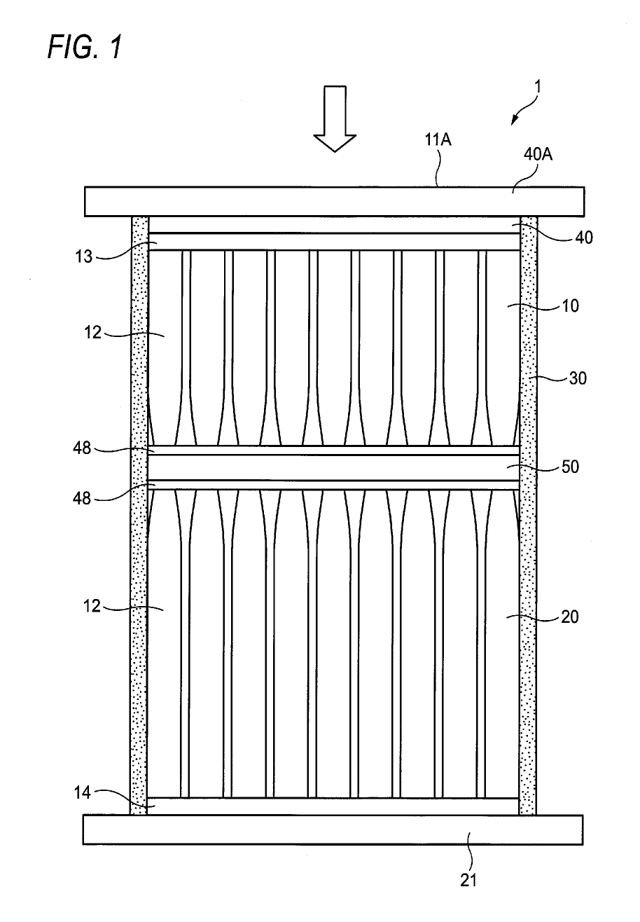

An example of an X-ray image detection apparatus (a radiological image detection apparatus) to explain an embodiment of the present invention will be explained with reference to FIG. 1 to FIG. 7B hereinafter.

Here, the same reference symbols are affixed to the similar configurations to those being already described, and their explanations will be omitted or simplified hereinafter.

In the following, explanation will be made by taking an X-ray image detection apparatus as one type of the radiological image detection apparatuses. A configuration described hereinafter is applicable to the radiological image detection apparatuses using various radiations such as α rays, β rays, γ rays, etc. According to these radiological image detection apparatuses using various radiations such as α rays, β rays, γ rays, etc., the operations and effects substantially similar to those described hereinafter can be achieved.

### [1. Overall Configuration]

FIG. 1 is a side sectional view showing schematically a schematic configuration of an X-ray image detection apparatus 1 in the indirect conversion system. The X-ray image detection apparatus 1 includes a first scintillator 10 and a second scintillator 20 containing the fluorescent material that emits fluorescent lights in response to the irradiation of X rays (outline arrow in FIG. 1), first and second photodetectors 40, 50 for detecting the fluorescent lights emitted from these first and second scintillators 10, 20 as electric signals, a protection film 30 for covering the first and second scintillators 10, 20, and control modules (not shown) provided to the second scintillator 20 on the opposite side to the X-ray incident side respectively.

That is, in the X-ray image detection apparatus 1, the first photodetector 40, the first scintillator 10, the second photodetector 50, the second scintillator 20, and the control modules are arranged in this order from the X-ray incident side.

The protection film 30 seals the first and second scintillators 10, 20 and the second photodetector 50 between a insulating substrate 40A, onto which the first scintillator 10 is deposited, and a support 21, onto which the second scintillator 20 is deposited. This protection film 30 is formed of parylene, or the like by the vapor deposition method. The parylene protection film 30 has good adhesion performance to the first and second scintillators 10, 20, and also has flexibility. Therefore, this protection film 30 has good follow-up performance to a bowing of the insulating substrate 40A and the support 21, and the like.

In the X-ray image detection apparatus 1, the X rays (outline arrow) that passed through a subject are irradiated toward the second scintillator 20 side from the first scintillator 10 side. A surface of the first photodetector 40 constitutes an X-ray incident plane 11A. The X rays are absorbed by the first scintillator 10 and are converted into the fluorescent lights there, then are passed through the first photodetector 40 and are also incident on the second scintillator 20, and then are converted into the fluorescent lights in the second scintillator 20. The fluorescent lights emitted from the first scintillator 10 are incident on both the first photodetector 40 and the second photodetector 50. The fluorescent lights emitted from the second scintillator 20 are incident mainly on the second photodetector 50. Accordingly, The electric charges are accumulated in the PDs that are provided to the first and second photodetectors 40, 50 respectively, and these electric charges are output by TFTs as electric signals.

In an example shown in FIG. 1, a thickness of the second scintillator 20, which are located away from the X-ray incident plane 11A, is set larger than a thickness of the first scintillator 10, so that an increase of an amount of luminescence of the second scintillator 20 can be attained. In this case, respective thicknesses of the first and second scintillators 10, 20 can be decided appropriately.

Each of the control modules (not shown) has ICs as controlling portions for driving/controlling the photodetector 40, a circuit substrate on which an IC for processing image signals, etc. are mounted, a power supply circuit, and the like. The control modules are assembled integrally with the first and second scintillators 10, 20 and the first and second photodetectors 40, 50.

### [2. Configuration of Photodetectors]

(First Photodetector)

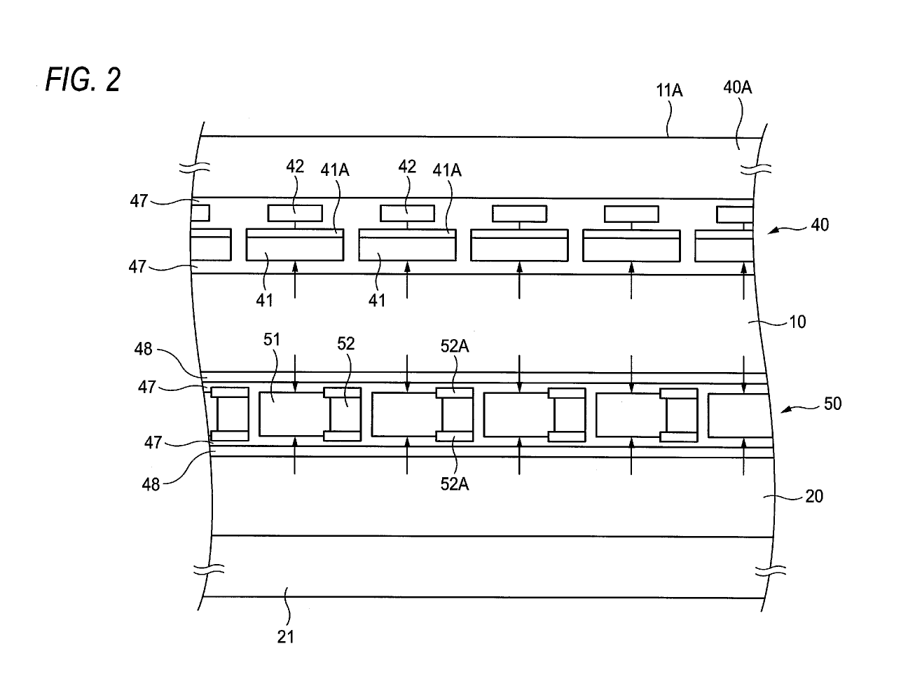

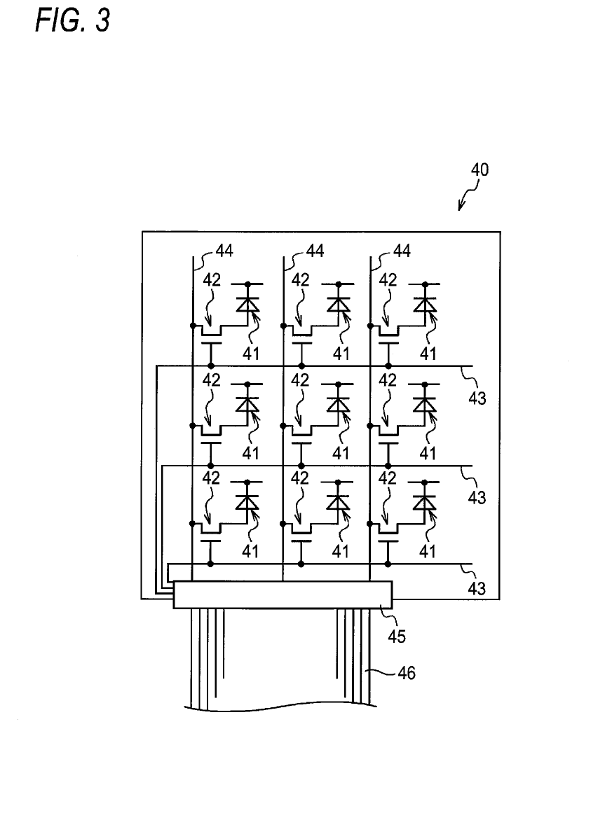

FIG. 2 is a side sectional view showing schematically the first and second photodetectors 40, 50. FIG. 3 is a plan view showing the elements that are two-dimensionally aligned.

The first photodetector 40 has PDs (Photodiodes) 41 each formed of a-Si, or the like, TFTs (Thin Film Transistors) 42 as the thin film switching devices each formed of a-Si, or the like, and the insulating substrate 40A on which the PDs 41 and the TFTs 42 are formed. The first scintillator 10 is deposited on the first photodetector 40.

The PD 41 has a photoelectric layer that converts the lights, which are incident mainly from the first scintillator 10 (arrows indicated with a solid line respectively in FIG. 2) into the electric charges. Each PD 41 corresponds to a pixel of the image being detected by the first photodetector 40.

A reflecting layer 42A for suppressing occurrence of the switching noise of the TFT 42 is provided to end portions of the TFTs 42 on the PD 41 side respectively.

In each PD41, as shown in FIG. 3, the TFT 42, a gate line 43, and a data line 44 are provided respectively. Each gate line 43 and each data line 44 are provided to extend to a connection terminal 45, and are connected to the circuit substrate of the control module via a flexible wiring 46 such as an anisotropic conductive film, or the like, which is connected to this connection terminal 45. According to the control signal that is fed through the gate line 43 from the controlling portion that is mounted on the circuit substrate, the ON/OFF of respective TFTs 42 is switched on a row basis. Then, the electric charges of the PD 41 whose TFT 42 is in its ON state are read out to a signal processing portion of the circuit substrate as an image signal via the data line 44. When the electric charges of the PD 41 are read out sequentially on a row basis, the two-dimensional image is detected.

(Second Photodetector)

The second photodetector 50 has PDs (Photodiodes) 51 each formed of a-Si, or the like, and TFTs (Thin Film Transistors) 52 as the thin film switching devices each formed of a-Si, or the like. Also, the PDs 51 and the TFTs 52 are two-dimensionally aligned, like the PDs 41 and the TFTs 42 shown in FIG. 3.

The PD 51 has a photoelectric layer that converts the lights, which are incident from both the first and second scintillators 10, 20 (arrows indicated with a solid line respectively in FIG. 2) into the electric charges. Each PD 51 corresponds to a pixel of the image being detected by the second photodetector 50. A resolution of the first photodetector 40 and a resolution of the second photodetector 50 may be set equally or differently.

The TFT 52 is arranged in the position adjacent planarly to the PD 51 on the identical plane or substantially identical plane to the PD 51. A reflecting layer 52A for suppressing occurrence of the switching noise of the TFT 52 is provided on both sides of the TFT 52 in the thickness direction respectively.

The PDs 51 and the TFTs 52 are formed on a substrate (not shown) made of metal such as Al, or the like, made of glass, or the like by the photo etching process, or the like, and then are peeled off from this substrate. In other words, since the substrate is removed from the PDs 51 and the TFTs 52 of the second photodetector 50, the X rays are never absorbed by the substrate. Hence, not only the X-ray dose that is incident on the second scintillator 20 via the first scintillator 10 can be increased, but also the lights emitted from the second scintillator 20 can be incident on the PDs 51 without absorption in the substrate. As a result, an amount of lights incident on the PDs 51 can also be increased. Also, the peeled substrate can be reused, and a reduction in cost can be attained.

With regard to the method of peeling off the PDs 51 and the TFTs 52 from the substrate, the literatures such as JP-A-2000-133809, JP-A-2003-66858, JP-A-2003-45890, and the like are informatively utilized.

Here, the similar advantages to the substrate peeling can be attained by thinning or removing the substrate by means of the chemical dissolving method or the polishing method, in addition to the peeling of the substrate.

In FIG. 2, both side surfaces of the second photodetector 50 in the thickness direction are planarized by a resin film 47. But this resin film 47 may be omitted. The second photodetector 50 is pasted on the first and second scintillators 10, 20 via an adhesive layer 48 respectively. Thus, the first and second scintillators 10, 20 adhere closely to the second photodetector 50 via the adhesive layer 48 respectively.

Here, the adhesive layer 48 and the resin film 47 may be eliminated between the first and second scintillators 10, 20 and the second photodetector 50 respectively. Also, the first and second scintillators 10, 20 may be pressed against the surface of the second photodetector 50 respectively, and be forced to stick directly to this surface.

The resins constituting the resin layers such as the planarization layer, the adhesive layer, the matching oil layer formed of a transparent liquid or a gel, etc., which are provided between the second photodetector 50 and the first and second scintillators 10, 20 respectively, are not particularly limited. Any resins may be used if these resins scarcely attenuate the scintillation light being emitted from the first and second scintillators 10, 20 and allows such light to reach the second photodetector 50.

As the resin constituting the planarization layer, polyimide, parylene, and the like can be used. The polyimide whose deposition property is good is preferable.

As the adhesives constituting the adhesive layer, the material that is optically transparent to the scintillation light being emitted from the first and second scintillators 10, 20 is preferable. For example, a thermoplastic resin, a UV cure adhesive, a thermosetting adhesive, a room-temperature curable adhesive, a double-sided adhesive sheet, and the like may be listed. From the viewpoint that sharpness of the image is not degraded, it is referable that, because an adhesive layer that is made sufficiently thinner than a pixel size of the second photodetector 50 can be formed, the adhesive made of a low viscosity epoxy resin should be employed.

Also, from the viewpoint of sensitivity and picture quality, it is preferable that a thickness of the resin layers such as the planarization layer, the adhesive layer, etc. should be set to 50 μm or less. It is more preferable that a thickness of such resin layers should be set within a range of 5 μm to 30 μm.

### [3. Configuration of Scintillators]

### [3-1. Support]

The support 21 on which the second scintillator 20 are deposited is formed of the material such as Al, or the like, which reflects the lights, like a plate. The support 21 is not restricted to the plate made of Al, and can be chosen appropriately from a carbon plate, CFRP (carbon fiber reinforced plastic), a glass plate, a quartz substrate, a sapphire substrate, and the like. Also, the support 21 is not particularly restricted to them so far as the scintillator can be formed on the surface of the support. Here, in case the support 21 is also used as a light reflecting member, preferably a light metal such as Al, or the like may be used as the material of the support. Since the support 21 is arranged on the opposite side to the X-ray incident plane 11A, such support 21 may be formed of the material whose X-ray transmittance is low.

The first scintillator 10 is deposited on the first photodetector 40, as described above.

In this case, the support 21 and the insulating substrate 40A are not essential to the X-ray image detection apparatus 1. That is, the scintillator can be deposited/formed on the support 21 and the first photodetector 40 by the vapor deposition, and then such scintillator can be peeled off from the support 21 and the insulating substrate 40A and can be used. Also, a light reflecting member can be provided on the opposite side of the second scintillator 20 to the second photodetector 50 side.

### [3-2. Fluorescent Material]

The first and second scintillators 10, 20 are formed by adding Tl to a base material of CsI as an activator. An amount of luminescence can be enhanced by adding Tl.

The first and second scintillators 10, 20 in this example are formed by a group of columnar crystals in which the fluorescent material is grown like columns, and are formed by using CsI:Tl (thallium-activated cesium iodide) as the material. Further, NaI:Tl (thallium-activated sodium iodide), CsI:Na (sodium-activated cesium iodide), and the like can be used as the material of the first and second scintillators 10, 20. Because the emission spectrum is fit for a maximal value (around 550 nm) of the spectral sensitivity of the a-Si photodiode, it is preferable that CsI:Tl should be used as the material.

Here, the first and second scintillators 10, 20 may be formed to contain no columnar crystal. For example, the first and second scintillators 10, 20 may be formed by applying GOS (Gd₂O₂S:Tb (terbium-activated gadolinium trisulfide)) to the support.

### [3-3. Distance Between Scintillators]

As described above, the second photodetector 50 is obtained by peeling off from the substrate and also the PDs 51 and the TFTs 52 are arranged such that they are adjacent planarly to each other. Therefore, the first and second scintillators 10, 20 are arranged in very close vicinity to each other. It is preferable that a distance between the mutually opposing surfaces of the first and second scintillators 10, 20 should be set to 40 μm or less. More preferably, such distance should be set to 30 μm or less. In this manner, MTF can be improved by shortening the distance between the first and second scintillators 10, 20.

Here, when the substrate formed by the organic material whose absorbed dose of the X ray and the fluorescence is low is employed as the substrate on which the PDs and the TFTs of the second photodetector are formed, such an approach can be considered that the substrate is not peeled off. In this case, it is preferable that the substrate should be peeled off because a distance between the first and second scintillators can be shortened by peeling off the substrate.

### [3-4. Crystal Structure of Scintillators]

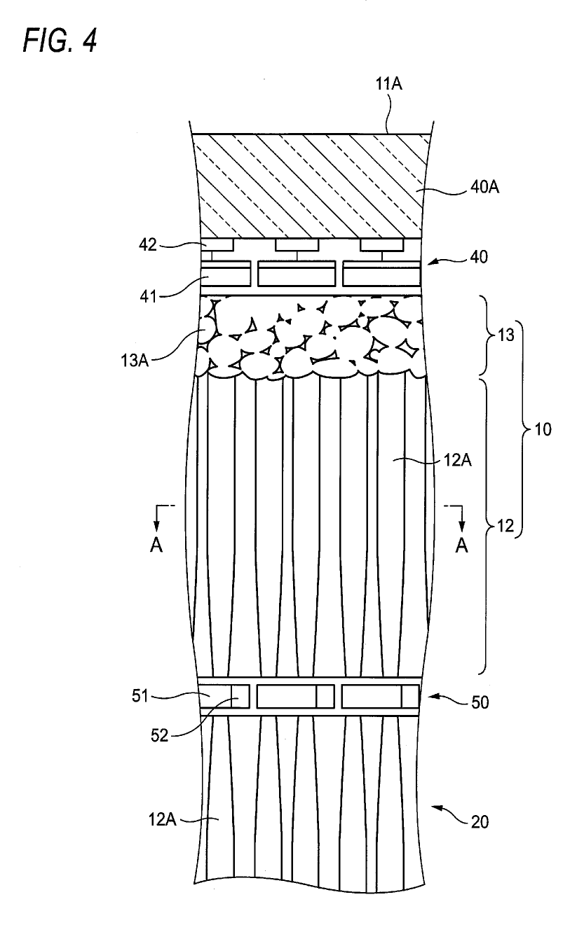

FIG. 4 is a side sectional view showing schematically the crystal structure of the first scintillator 10. The first scintillator 10 has a columnar portion 12 formed of a group of the columnar crystals 12A, and a non-columnar portion 13 containing non-columnar crystals 13A that are formed on the base ends of the columnar crystals 12A. The non-columnar portion 13 fulfills the role of improving the adhesion between the first photodetector 40 and the first scintillator 10.

Also, the second scintillator 20 has the columnar portion 12 and a non-columnar portion 14 formed substantially similarly to the non-columnar portion 13 (FIG. 1), which are substantially similar to the first scintillator 10. The non-columnar portion 14 of the second scintillator 20 has the light reflecting characteristics, in addition to the function of improving the adhesion between the support 21 and the second scintillator 20.

The fluorescent lights being emitted from the first scintillator 10 in response to the irradiation of the X rays are guided in the height direction of the columns (the crystal growth direction) by the columnar crystals 12A, and then are incident on the first and second photodetectors 40, 50 respectively. Also, the fluorescent lights being emitted from the second scintillator 20 in response to the irradiation of the X rays onto the second scintillator 20 are incident on the second photodetector 50. At this time, the lights that travel toward the support 21 side are reflected by the non-columnar portion 14 and the support 21, and then are incident on the second photodetector 50.

(Configuration of the Columnar Portion)

The columnar portion 12 is an assembly of a large number of columnar crystals 12A, and the columnar crystals 12A stand up substantially perpendicularly on the first photodetector 40 in an example shown in FIG. 4. The columnar crystals 12A are formed such that their top end sides become narrower gradually. The top end portions of the columnar crystals 12A may be polished respectively. Top end portions and base end portions of a plurality of columnar crystals 12A are opposed to unit pixels (PDs 41, 51) of the first and second photodetectors 40, 50 respectively.

The columnar crystals 12A have good crystallinity in contrast to the non-columnar crystal, and have a large amount of luminescence of the fluorescent lights respectively. Also, the columnar crystals 12A adjacent to each other via a void are provided to stand up in the thickness direction of the first scintillator 10 (second scintillator 20). Therefore, the columnar crystal 12A acts as a guide of light to guide the lights in the height direction of the columns. Since the diffusion of the lights between the pixels can be suppressed based on the light guiding effect given by the columnar crystal 12A, sharpness of the detected image can be increased.

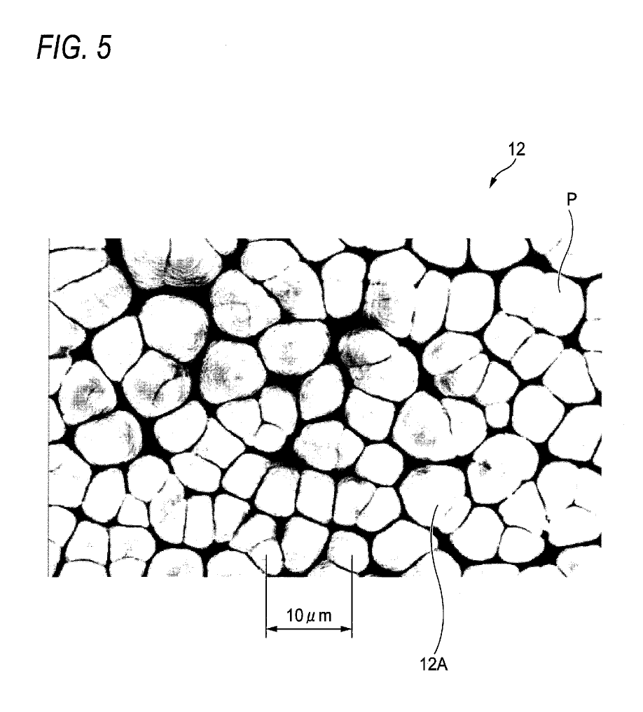

FIG. 5 is an electron microscope photograph of the columnar portion 12 taken in an A-A section (an almost center section in the height direction of the columnar portion 12) in FIG. 4. There are voids between the adjacent columnar crystals 12A (portions that appear to be dark in FIG. 5). Each of the columnar crystals 12A has an almost uniform sectional diameter in the growth direction of the crystal. The adjacent columnar crystals 12A are bonded together in a part of the region of the columnar portion 12 to constitute one columnar body (for example, P in FIG. 5).

In view of an X-ray absorptive power corresponding to a required sensitivity, a thickness of the columnar portion 12 is set to about 200 μm in the mammography application, and is set to 500 μm or more in the common radiographic application. In this case, even though a thickness of the columnar portion 12 is set too thick, a utilization factor of light emission tends to decrease due to absorption, scattering, etc. of light. Therefore, a thickness of the columnar portion 12 is decided at an appropriate value while considering a sensitivity and a utilization factor of light emission respectively.

(Configuration of the Non-Columnar Portion)

First, the non-columnar portion 14 of the second scintillator 20 (FIG. 1) will be explained hereunder.

The non-columnar portion 14 is constructed to contain the substantially spherical or indefinite non-columnar crystals 13A, which are substantially similar to the crystal structure of the non-columnar portion 13 shown in FIG. 4. In some cases, the non-columnar portion 14 and the non-columnar portion 13 contain the amorphous part.

From the viewpoint that a void is maintained easily between the crystals respectively and a reflection efficiency can be made high, it is preferable that the non-columnar crystals 13A should be formed like a substantial spherical shape. That is, it is preferable that the non-columnar portion 14 should be constructed by an assembly of quasi-spherical crystals (the non-columnar crystals 13A as the substantially spherical crystals).

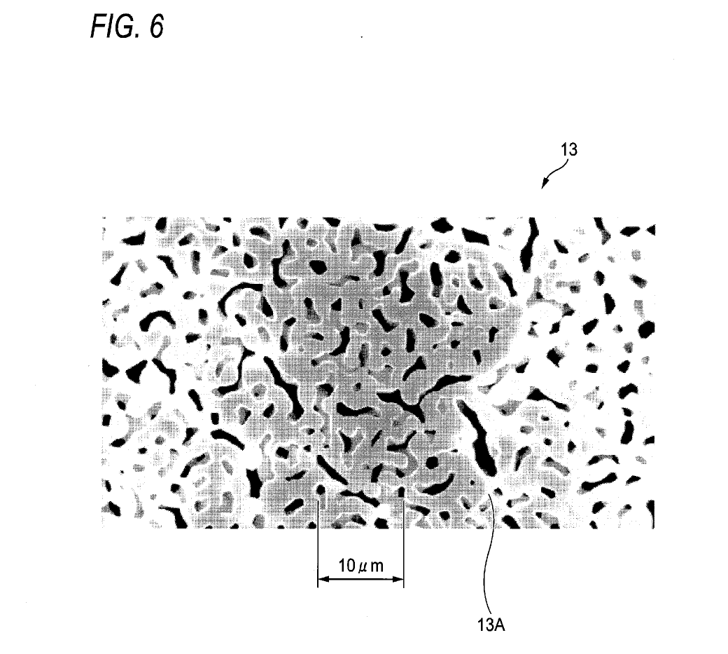

FIG. 6 is an electron microscope photograph of the non-columnar portion 14 taken in a B-B section (section on the base end side in the thickness direction of the non-columnar portion 14) in FIG. 4. In the non-columnar portion 14, the non-columnar crystals 13A each having a smaller diameter than that of the columnar crystal 12A in FIG. 5 are bonded irregularly to each other or are overlapped with each other, and thus a clear void seldom appears between the crystals. The voids in FIG. 6 are smaller in number than the voids in FIG. 5. It is appreciated from the observation results in FIG. 5 and FIG. 6 that a void ratio of the non-columnar portions 13 is lower than a void ratio of the columnar portions 12.

A void ratio of the non-columnar portions 13 is calculated based on a deposition area of the non-columnar portion 14 on the support 21, a thickness of the non-columnar portion 14, a CsI density, an actually measured weight of the scintillator panel, and the like. A total void ratio calculated in such manner in the thickness direction of the non-columnar portion 14 is less than 10%.

The non-columnar portion 14 corresponds to the region that is formed in the initial stage of the vapor deposition on the support 21. A void ratio of the part that contacts a surface of the support 21 in the non-columnar portion 14 becomes 0 or almost 0. The base end portion of the non-columnar portion 14 is adhered closely to the support 21 on its whole contact surface to the support 21.

It is preferable that a thickness of the non-columnar portion 14 should be set thinner than a thickness of the columnar portion 12, and be set to 5 μm or more but 125 μm or less. In order to maintain the adhesion to the support 21, it is preferable that a thickness of the non-columnar portion 14 should be set to 5 μm or more. Also, when a thickness of the non-columnar portion 14 that has no light guiding effect is set too thick, the lights are intermixed between the pixels in the non-columnar portion 14, and thus blurriness of the image is easily caused. Therefore, it is preferable that a thickness of the non-columnar portion 14 should be set to 125 μm or less.

Also, a minimum thickness that enables the non-columnar portion 14 to get adhesion to the support 21 and a light reflecting function will suffice for the thickness of the non-columnar portion 14.

Here, according to the manufacturing conditions, etc., in some cases the non-columnar portion 14 is constructed by not a single layer but laminated plural layers. In such case, a thickness of the non-columnar portion 14 denotes a sum thickness that is added from a surface of the support 21 to a surface of the outermost layer of the non-columnar portion 14.

In the measurement of the crystal diameter in the situation that the adjacent crystals are adhered like the non-columnar portion 14, a line that is set by connecting the recesses (concave portions) produced between the adjacent non-columnar crystals 13A is regarded as a grain boundary between the crystals, then the adhered crystals are separated to form a minimum polygon and then respective crystal diameters are measured, then an average value of the measured crystal diameters is taken in the similar way to that of the diameter of the columnar crystals 12A in the columnar portion 12, and then the value is adopted as the crystal diameter.

From the viewpoint that the effective reflecting characteristic and the adhesion to the support 21 are given to the non-columnar crystal 13A, it is preferable that a diameter of the non-columnar crystal 13A in the non-columnar portion 14 should be kept more than 0.5 μm but less than 7.0 μm. The diameter of the non-columnar crystal 13A is smaller than the diameter of the columnar crystal 12A.

Here, it is preferable that the diameter of the non-columnar crystal 13A should be formed smaller because the substantially spherical crystal shape can be easily maintained. In this case, when the diameter of the non-columnar crystal 13A is excessively smaller, a void ratio comes closer to 0, and thus the non-columnar portion 14 does not fulfill a role of the light reflecting layer. Therefore, it is preferable that the diameter of the non-columnar crystal 13A should be kept more than 0.5 μm. In contrast, when the diameter of the non-columnar crystal 13A is excessively larger, evenness and a void ratio of the non-columnar portion 14 are degraded, and the adhesion to the support 21 is lowered. Also, because the crystals are bonded mutually, a void ratio is decreased and the reflection effect is lessened. Therefore, it is desirable that the crystal diameter of the non-columnar portion 14 should be kept less than 7.0 μm.

Since such non-columnar portion 14 is formed, the columnar crystal 12A can be grown on a base of the non-columnar portion 14 in such a state that its crystallinity is kept good.

Also, the lights can be emitted from the columnar portions 12 of the second scintillator 20 whose crystallinity is kept good, and then the lights that travel toward the opposite side to the second photodetector 50 can be reflected by the non-columnar portion 13 and be forced to input into the second photodetector 50. Therefore, an amount of incident light into the sensor portion is increased, and an available amount of luminescence can be enhanced. A diameter, a thickness, a void ratio, etc. of the non-columnar crystal 13A are decided by taking account of the light reflecting characteristics, adhesion to the support 21, and the like.

Since the non-columnar portion 14 is provided to the second scintillator 20, the adhesion between the support 21 and the second scintillator 20 is improved. Therefore, the second scintillator 20 can be made it hard to peel off from the support 21 even in the transfer of heat from the control module.

The non-columnar portion 13 that the first scintillator 10 possesses is formed substantially similarly to the non-columnar portion 14 of the second scintillator 20. However, The non-columnar portion 13 of the first scintillator 10 does not have the light reflecting characteristic, unlike the non-columnar portion 14 that the second scintillator 20 possesses. A diameter, a thickness, and a void ratio of the non-columnar portion 13 may be decided appropriately to hold the adhesion between the first photodetector 40 and the first scintillator 10. In order to improve the adhesion to the first photodetector 40, it is preferable that a void ratio in the part, which contacts the surface of the first photodetector 40, of the non-columnar portion 13 should be reduced to 0 or almost 0.

### [3-5. Manufacturing Method]

It is preferable that the above first and second scintillators 10, 20 should be formed by the vapor deposition method. Here, explanation will be made by taking the mode using CsI:Tl as an example.

As to the summary of the vapor deposition method, in the environment of a degree of vacuum 0.01 to 10 Pa, CsI as a base material and Tl as an activator are heated and vaporized by the means that feeds an electric power to the resistance heating type crucible, or the like respectively, and then CsI:Tl is deposited on the support (or the substrate of the photodetector) by setting a temperature of the support to a room temperature (20° C.) to 300° C.

Here, when the Tl heating temperature is changed by changing an electric power applied to the Tl crucible, a degree of vacuum is changed, or the like, the scintillator whose activator density is different in the crystal growth direction can be formed. For example, an activator density can be enhanced by increasing an electric power applied to the Tl crucible whereas an activator density can be lowered by decreasing an electric power applied to the Tl crucible. In addition, an activator density can be changed by exchanging the type of the activator such as thallium sulfate, thallium oxide, thallium iodide, thallium carbonate, or the like (changing the Tl containing compound). An activator density may be changed by combining the change of the Tl containing compound with the change of a deposition cell temperature. Further, an activator density may be changed by the doping using the ion implantation.

Also, a crystal profile, a crystal diameter, a void ratio, etc. of the second scintillator 20 can be controlled by changing a degree of vacuum, a temperature of the support, a deposition rate, or the like.

The above first and second scintillators 10, 20 and the first and second photodetectors 40, 50 are assembled together as follows. With regard to the first photodetector 40 and the first scintillator 10, TFTs 42 and PDs 41 of the first photodetector 40 and the first scintillator 10 are formed on the insulating substrate 40A. Also, the second photodetector 50 is formed on a substrate (not shown) by depositing the second scintillator 20 on the support 21 (second photodetector forming step). Then, the first photodetector 40 and the first scintillator 10, which are assembled integrally, and the second photodetector 50 are pasted together, and then the second photodetector 50 and the second scintillator 20 are pasted together.

At this time, one of the first and second scintillators 10, 20 is pasted onto the second photodetector 50 together via the adhesive layer 48, and then a substrate (not shown) is peeled off from the second photodetector 50 (substrate peeling step). Then, the other of the first and second scintillators 10, 20 and the second photodetector 50 are pasted together via the adhesive layer 48, and then the protection film 30 is formed. Thus, the X-ray image detection apparatus 1 is manufactured.

Here, the deposition substrate of the second photodetector 50 is peeled off/removed from the second photodetector 50 in any case. Therefore, there is no necessity that a transparent substrate such as glass, or the like should be used as the deposition substrate of the second photodetector 50, and thus a metal deposition substrate can be used. It is impossible to say that adhesion between the glass, or the like, whose thermal conductivity is low, and CsI is good. Therefore, adhesion between the second photodetector 50 and the first scintillator 10 can be improved by depositing the scintillator on the photodetector that is formed on the metal deposition substrate.

In this case, when the moisture-proof of respective scintillators can be attained by other means, for example, when the first and second scintillators 10, 20 are wrapped in an airtight and watertight manner by the moisture-proof film, the protection film 30 may not be formed.

Also, the method of adhering the first and second scintillators 10, 20 and the second photodetector 50 together is not particularly restricted. Any method may be employed if both members can be optically adhered. As the method of adhering both members together, either of the method of causing both members to oppose directly to each other and adhering them together and the method of causing both members to adhere together via the resin layer may be adopted.

### [3-6. Activator Density (Activator Density)]

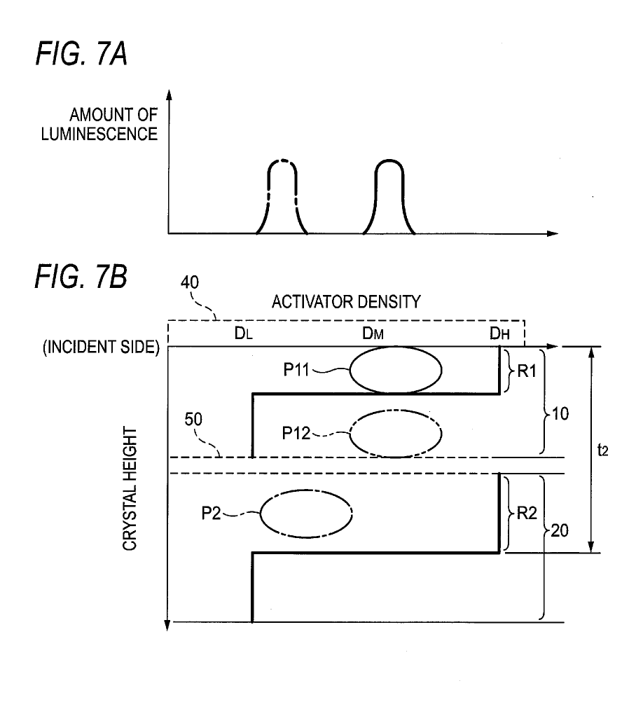

FIG. 7B shows activator density distributions of the first and second scintillators 10, 20. In FIG. 7B, the positions in which the first and second photodetectors 40, 50 are schematically indicated with a broken line.

A high activator density region R₁, in which an activator density is relatively higher than an average of the activator density in the first scintillator 10, is provided in vicinity of the first photodetector 40 in the first scintillator 10.

Also, a high activator density region R₂, in which an activator density is relatively higher than an average of the activator density in the second scintillator 20, is provided in vicinity of the second photodetector 50 in the second scintillator 20.

Respective thicknesses of the high activator density regions R₁, R₂ are decided appropriately. In the case in FIG. 7B, respective averages of the activator densities of the first and second scintillators 10, 20 are decided based on a thickness of the region that is set at a high density D_{H} and a thickness of the region that is set at a low density D_{L} in respective scintillators, and is set to a density between the high density D_{H} and the low density D_{L} (e.g., a middle density D_{M}).

The activator densities in the high activator density regions R₁, R₂ are set to the same high density D_{H} in an example in FIG. 7B, and may be set differently. The low density D_{L} may be set to 0. That is, the low density part may be formed of CsI in which Tl is not added.

FIG. 7A shows an amount of luminescence of the first and second scintillators 10, 20 respectively. An amount of luminescence indicated with a solid line in FIG. 7A corresponds to an amount of luminescence of the lights that are emitted from the first scintillator 10 and are incident on the first and second photodetectors 40, 50 respectively. This amount of luminescence contains an amount of luminescence in a part P11 of the first scintillator 10 shown in FIG. 7B, and an amount of luminescence in a part P12 of the first scintillator 10.

In contrast, an amount of luminescence indicated with a dot-dash line in FIG. 7A corresponds to an amount of luminescence of the lights that are incident mainly on the second photodetector 50. This amount of luminescence contains an amount of luminescence contains an amount of luminescence in a part P2 of the second scintillator 20 shown in FIG. 7B.

Two mountain-like profiles showing amounts of luminescence indicated with a solid line and a dot-dash line in FIG. 7A denote a steepness of the amounts of luminescence, which correspond to widths of the parts P11, P12 and P2 respectively. The activator densities in these parts P11, P12 and P2 are not associated with the abscissa in FIG. 7B, and all activator densities in these parts P11, and P2 correspond to the high density D_{H} respectively.

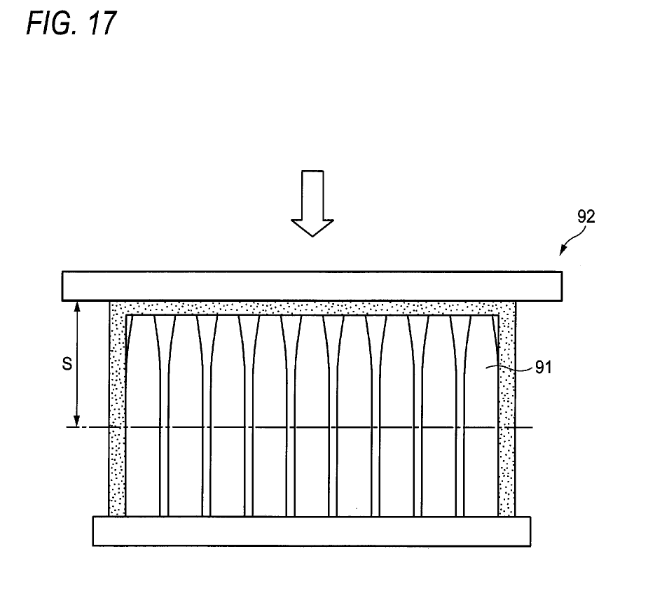

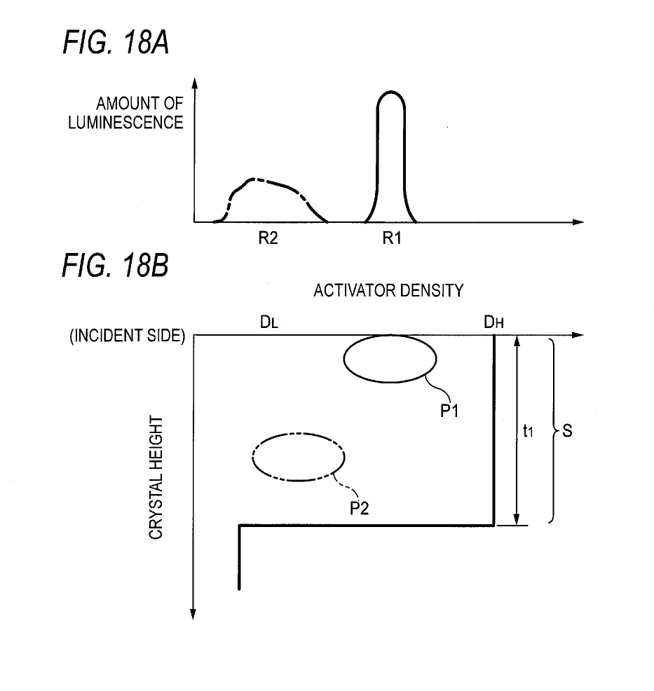

Here, in the comparison between FIG. 18A and FIG. 7A showing an activation density distribution in the case where only one scintillator is employed (FIG. 17), an amount of luminescence of the second scintillator 20 indicated with a dot-dash line in FIG. 7A is larger and steeper than an amount of luminescence indicated with a dot-dash line in FIG. 18A. Unlike the configuration of the X-ray image detection apparatus in FIG. 17 in which the photodetector 92 is provided only to the X-ray incident side of the scintillator 91, in addition to the first photodetector 40 constituting the X-ray incident plane 11A, the second photodetector 50 is also provided between the first and second scintillators 10, 20 in the configuration in FIG. 7A and FIG. 7B. Therefore, the fluorescent lights emitted from the part P2 of the second scintillator 20 are incident on the second photodetector 50 a light path length of which is shorter than a light path length to the first photodetector 40. A light absorption is decreased because the light path length is shorter. Here, as described above, the substrate is peeled off from the second photodetector 50 and a distance between the first and second scintillators 10, 20 is very small (less than 40 μm), and therefore a light path length can be reduced very small. With the above, an available amount of luminescence of the lights that are emitted from the second scintillator 20 and are incident on the second photodetector 50 becomes large and steep like an amount of luminescence indicated with a dot-dash line in FIG. 7B.

Also, in FIG. 18A, an amount of luminescence indicated with a solid line and an amount of luminescence indicated with a dot-dash line are different in magnitude and steepness. In contrast, in FIG. 7A, an amount of luminescence of the first scintillator 10 indicated with a solid line and an amount of luminescence of the second scintillator 20 indicated with a dot-dash line are substantially equal in magnitude and steepness.

In the scintillator 91 of the X-ray image detection apparatus shown in FIG. 17, an activator density is high throughout the thickness of the scintillator, as shown in FIG. 18B. In contrast, in the configuration in FIG. 7B, only an activator density of the part of the first scintillator 10 located in vicinity of the first photodetector 40 is high, and an activator density of the part of the first scintillator 10 located away from the first photodetector 40 is low. Therefore, with regard to this respect, an amount of luminescence indicated with a solid line in FIG. 7A becomes lower than an amount of luminescence indicated with a solid line in FIG. 18A.

On the contrary, unlike the configuration in FIG. 17 in which the photodetector is provided only to the scintillator on the X-ray incident side, the fluorescent lights emitted from the part P12, which is located away from the first photodetector 40 but close to the second photodetector 50, of the first scintillator 10 are incident on the second photodetector 50 in the configuration in FIG. 7A and FIG. 7B. In other words, even though an activator density of the part P12 of the first scintillator 10 is not high unlike the high activator density region R₁, an amount of luminescence of the first scintillator 10 is sufficiently large because the part P12 is located close to the second photodetector 50. Since a light path length between the part P12 and the second photodetector 50 is short, steepness of the amount of luminescence is also sufficiently sharp.

As described above, in the configuration that the second photodetector 50 is provided between the first and second scintillators 10, 20, the activator densities of the first and second scintillators 10, 20 located in vicinity of respective photodetectors can be set high. For this reason, in the configuration that the X rays are irradiated onto the scintillator 91 from the photodetector 92 side on the X-ray incident side (FIG. 17), a further increase of an amount of luminescence and a further improvement in MTF can be achieved.

Accordingly, even when an amount of luminescence of the first scintillator 10 indicated with a solid line in FIG. 7A and FIG. 7B is smaller than an amount of luminescence indicated with a solid line in FIG. 17, a total amount of luminescence obtained by adding an amount of luminescence indicated with a solid line and an amount of luminescence indicated with a dot-dash line in FIG. 7A and FIG. 7B becomes larger than that in FIG. 17.

In other words, a thickness t₂ of the whole scintillators shown in FIG. 7A and FIG. 7B (a total thickness t₂ of the first and second scintillators) can be made smaller than a thickness t₁ of the scintillator in the case where only one scintillator is employed (FIG. 17). Therefore, a reduction in thickness can be accelerated, and also an amount of usage of the expensive fluorescent material can be reduced and a reduction in cost can be attained.

Here, in an example in FIG. 7B, the high activator density region is provided in both the first and second scintillators 10, 20. In this case, the high activator density region may be provided in either of the first and second scintillators 10, 20.

For example, in the case where the high activator density region R₁ is provided in the first scintillator 10 but the high activator density region R₂ is not provided in the second scintillator 20 and an activator density in the part P2 of the second scintillator 20 is low or 0, an amount of luminescence becomes smaller than an amount of luminescence indicated with a dot-dash line in FIG. 7A. In such case, an activator density of the first scintillator 10 in vicinity of the first photodetector 40 is kept high, and also the second photodetector 50 is provided between the first and second scintillators 10, 20. As a result, a further increase of a total amount of luminescence obtained by adding respective amounts of luminescence of the first and second scintillators 10, 20 and a further improvement in total MTF can be implemented.

In contrast, in the case where the high activator density region R₂ is provided in the second scintillator 20 but the high activator density region R₁ is not provided in the first scintillator 10 and an activator density in the part P11 of the second scintillator 20 is low or 0, an amount of luminescence becomes smaller than an amount of luminescence indicated with a solid line in FIG. 7A. In such case, an activator density of the second scintillator 20 in vicinity of the second photodetector 50 is kept high, and also the second photodetector 50 is provided between the first and second scintillators 10, 20. As a result, a further increase of a total amount of luminescence obtained by adding respective amounts of luminescence of the first and second scintillators 10, 20 and a further improvement in total MTF can be implemented.

Here, the high activator density regions R₁, R₂ are recited merely as an illustration of the high activator density region respectively. A concrete distribution of the activator density is not restricted as far as either an activator density of the first scintillator 10 in vicinity of the first photodetector 40 or an activator density of the second scintillator 20 in vicinity of the second photodetector 50 is higher than an average of the activator densities of these scintillators. For example, in the activator density distributions of the first and second scintillators 10, 20 in FIG. 7B, an activator density may be changed continuously with a gradient. Otherwise, an activator density may be changed stepwise in the crystal height direction.

As the above first and second photodetectors 40, 50, the insulating substrate 40A, the support 21, etc., for example, OPC (Organic Photoelectric Material), organic TFT, TFT using an amorphous oxide (e.g., a-IGZO), flexible material (aramid, bionanofiber), and the like can be used. These device related materials will be described later.

### [4. Operations and Effects of Activator Density]

According to the X-ray image detection apparatus 1 explained above, following operations and effects can be achieved. In the configuration that the first photodetector 40, the first scintillator 10, the second photodetector 50 being peeled off from the substrate, and the second scintillator 20 are provided in sequence from the X-ray incident side, the high activator density region R₁ is provided in the first scintillator in vicinity of the first photodetector 40. Therefore, while getting the effect of an increase in an amount of luminescence in the part P11 located near the first photodetector 40 to the utmost extent, an amount of luminescence in the part P12 that is away from the first photodetector 40 can be increased.

Also, in the configuration that the first photodetector 40, the first scintillator 10, the second photodetector 50 being peeled off from the substrate, and the second scintillator 20 are provided in sequence from the X-ray incident side, the high activator density region R₂ is provided in the second scintillator 20 in vicinity of the second photodetector 50. Therefore, an increase of an amount of luminescence and suppression of an expansion of emitted light in the second scintillator 20 located on the distant side from the X-ray incident plane 11A can be implemented.

With the above, in the configuration that the X rays are irradiated onto the scintillator 91 from the photodetector 92 side on the X-ray incident side, a further increase of an amount of luminescence and further improvement of MTF can be achieved by enhancing an activator density in a main luminescence region S of the scintillator on the X-ray incident side (FIG. 16). Accordingly, a detectivity and sharpness of the detected image can be improved.

### [5. Activator Density Distribution in Other Modes]

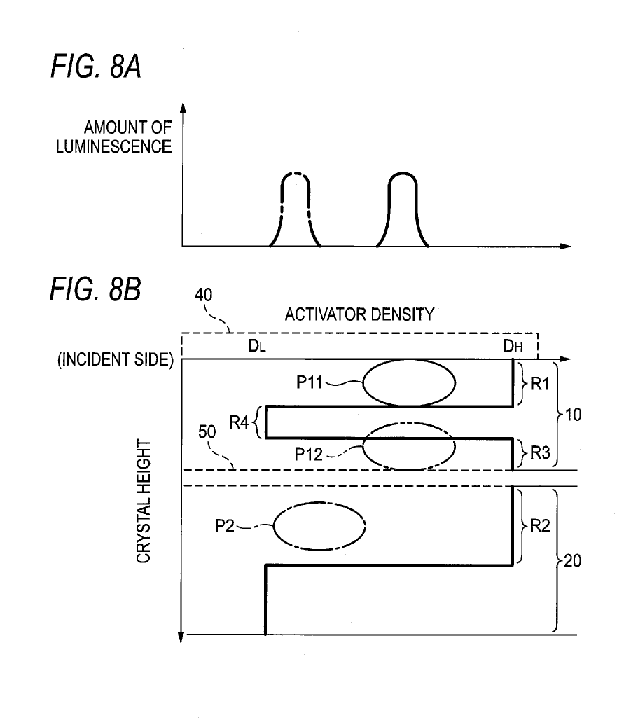

FIG. 8A and FIG. 8B show another activator density distributions applicable to the first and second scintillators. In the first scintillator 10 shown in FIG. 7A and FIG. 7B, the high activator density region R₁ is provided only in the vicinity of the first photodetector 40. In contrast, in the first scintillator 10 shown in FIG. 8A and FIG. 8B, a high activator density region R₃ in which an activator density is higher than an average of the activator density in the first scintillator 10 is also provided in vicinity of the second photodetector 50. In this manner, since an activator density in vicinity of the second photodetector 50 is set high, an amount of luminescence in the part P12 of in the first scintillator 10 that is distant from the first photodetector 40 but is close to the second photodetector 50 can be increased. Since the fluorescent lights emitted from the part P12 are incident on the second photodetector 50 whose light path length is shorter than that of the first photodetector 40, an amount of luminescence in the part P1 can be increased and also MTF can be improved.

Also, a low activator density region R₄ in which an activator density is lower than an average of the activator density in the first scintillator 10 is provided between the high activator density regions R₁, R₃ in the first scintillator 10. That is, the activator density distribution of the first scintillator 10 is set to high, low, and high in sequence from the X-ray incident side.

Here, the activator density of the first scintillator 10 is not restricted as far as the activator density in the region including the neighborhood of the first photodetector 40 is kept high. Also, the activator density may be set high through the almost entirety of a thickness of the first scintillator 10. An increase of an activator density in the regions that are positioned in the almost middle of the first and second photodetectors 40, 50 results in a reduction in sharpness of the image because a light absorbed amount in the concerned regions is increased larger than an increase of an amount of luminescence obtained by activating the concerned regions. Therefore, it is preferable that the activator density in the concerned regions should be decreased like the low activator density region R₄. By doing this, degradation of MTF caused due to an increase of an activator density can be suppressed.

A total amount of luminescence obtained by adding an amount of luminescence indicated with a solid line and an amount of luminescence indicated with a dot-dash like in FIG. 8A and FIG. 8B exceeds that in FIG. 18A and FIG. 18B. Also, unlike FIG. 18A and FIG. 18B in which a difference between an amount of luminescence indicated with a solid line and an amount of luminescence indicated with a dot-dash like is large, a difference between respective amounts of luminescence of the first and second scintillators 10, 20 in FIG. 8A and FIG. 8B is not so much. Also, since the high activator density region R₃ is provided to the first scintillator 10 in vicinity of the second photodetector 50, an amount of luminescence of the lights that are incident mainly on the second photodetector 50 is further increased in contrast to above FIG. 7A and FIG. 7B. As a result, an amount of luminescence can be increased further more.

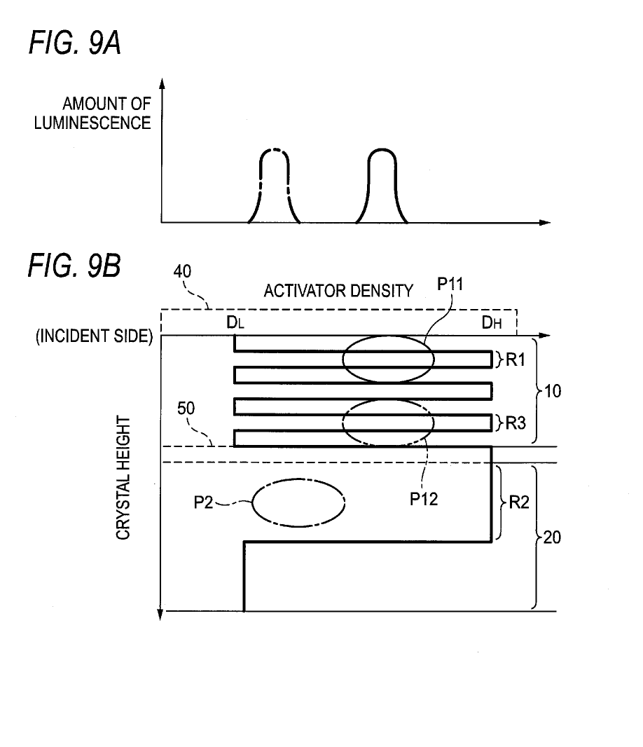

FIG. 9A and FIG. 9B show still another activator density distributions applicable to the first and second scintillators 10, 20. The activator density in the first scintillator 10 is changed repeatedly between the high density D_{H} and the low density D_{L} in the crystal height direction. An activator density shown in FIG. 9A and FIG. 9B is changed like a repetitive pulse of a rectangular wave. The number of repetition of the activator density change is not restricted. In such configuration, the high activator density region R₁ in which an activator density is higher than an average of the activator density in the first scintillator 10 is provided in the first scintillator 10 in the vicinity of the first photodetector 40.

Also, the high activator density region R₃ in which an activator density is higher than an average of the activator density in the first scintillator 10 is provided in the first scintillator 10 in vicinity of the second photodetector 50.

Here, depending upon a pulse width of the activator density, a pulse interval, etc., such a situation can be considered that a plurality of high activator density regions R₁ should be provided in the first scintillator 10 in vicinity of the first photodetector 40. Similarly, such a situation can be considered that a plurality of high activator density regions R₁ should be provided in the first scintillator 10 in vicinity of the second photodetector 50.

In contrast, like above FIG. 7A and FIG. 7B, and the like, an activator density of the second scintillator 20 is set substantially constant at the high density D_{H} at least in a part of the second scintillator 20 on the second photodetector 50 side.

According to the activator density distribution in FIG. 9A and FIG. 9B, the above operations and effects explained as above about the high activator density regions R₁ to R₃ respectively can also be enjoyed.

Here, the average of the activator density in the first scintillator 10 corresponds to the middle density D_{M} that lies between the high density D_{H} and the low density D_{L}. Consequently, an amount of luminescence is lower in at least a part of the first scintillator 10 than that in the case where the activator density is held substantially constant at the activator density that is higher than the average of the activator density. However, in comparison with FIG. 18A and FIG. 18B, a total amount of luminescence obtained by adding an amount of luminescence indicated with a solid line and an amount of luminescence indicated with a dot-dash line in FIG. 9A is sufficiently larger than that in FIG. 18A.

In addition to the above, the advantage of suppressing the disorder of crystallinity caused by the activation in the low density part can be attained by changing the activator density between the high density D_{H} and the low density D_{L} as shown in FIG. 9A and FIG. 9B. In particular, in the configuration that the first scintillator 10 is deposited on the first photodetector 40 as shown in FIG. 1, the part which is located on the X-ray incident side (the first photodetector 40 side) and whose activator density is high coincides with the initial stage of the crystal growth, and the disorder of crystallinity in the initial stage of this growth acts as a great factor to make worse the crystallinity in the part that is grown subsequently. As a result, the effect produced by increasing/decreasing an activator density in the crystal growth direction as shown in FIG. 9A and FIG. 9B is noticeable.

Here, a pulse width, a pulse interval, etc. can be decided appropriately in view of the crystallinity of the scintillator, and the like. Also, the high density pulse and the low density pulse may be set constant in height respectively or these pulses may be increased or decreased continuously or discontinuously.

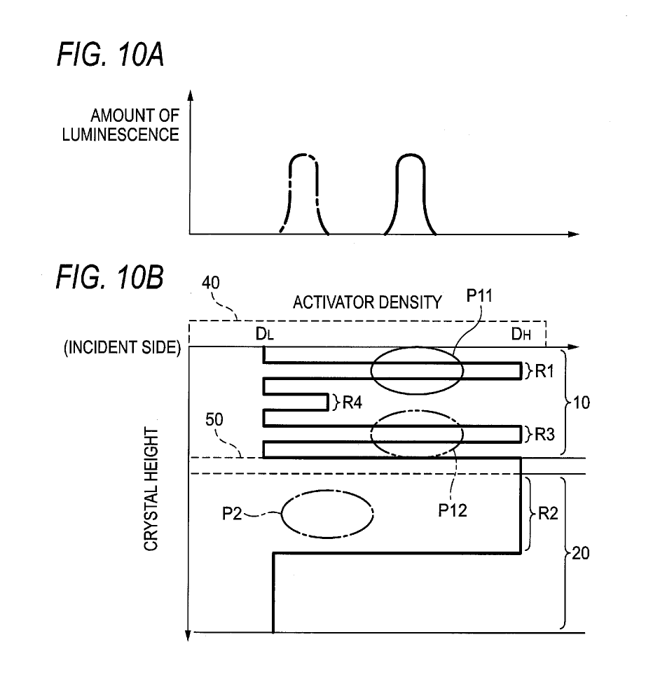

FIG. 10A and FIG. 10B show yet another activator density distributions applicable to the first and second scintillators 10, 20. The activator density distributions in FIG. 10A and FIG. 10B realize the activator density distributions as shown in FIG. 8A and FIG. 8B in the configuration in which the activator density is changed repeatedly as shown in FIG. 9A and FIG. 9B.

The low activator density region R₄ in which an activator density is lower than an average of the activator density in the first scintillator 10 is provided between the high activator density region R₁ and the high activator density region R₃ in the first scintillator 10.

According to the activator density distribution in FIG. 10A and FIG. 10B, the above operations and effects can be enjoyed by employing the high activator density regions R₁ to R₃, the low activator density region R₄, and the repetitive change of the activator density respectively.

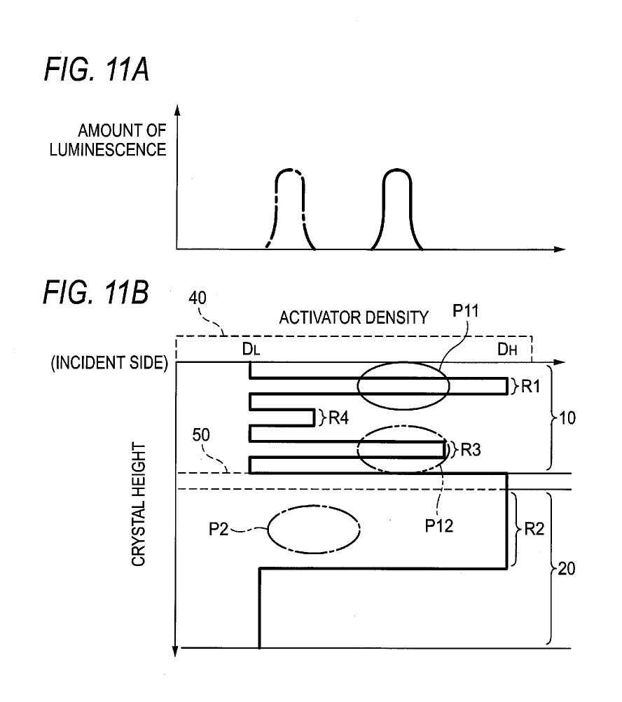

FIG. 11A and FIG. 11B show further activator density distributions applicable to the first and second scintillators 10, 20. As shown in FIG. 11A and FIG. 11B, the activator density in the high activator density region R₃ in vicinity of the second photodetector 50 may be set lower than the activator density in the high activator density region R₁ in vicinity of the first photodetector 40. That is, when the same activator density is given to respective regions, the effect of increasing a amount of luminescence in the high activator density region R₁ close to the X-ray incident plane 11A (FIG. 1) becomes larger than that in the high activator density region R₃ in vicinity of the second photodetector 50. Therefore, from the viewpoint that the effect of increasing an amount of luminescence consisting with the given activator density can be attained, it is preferable that the activator density in the high activator density region R₃ should be set lower than the activator density in the high activator density region R₁.

### [6. X-Ray Image Detection Apparatuses in Other Modes]

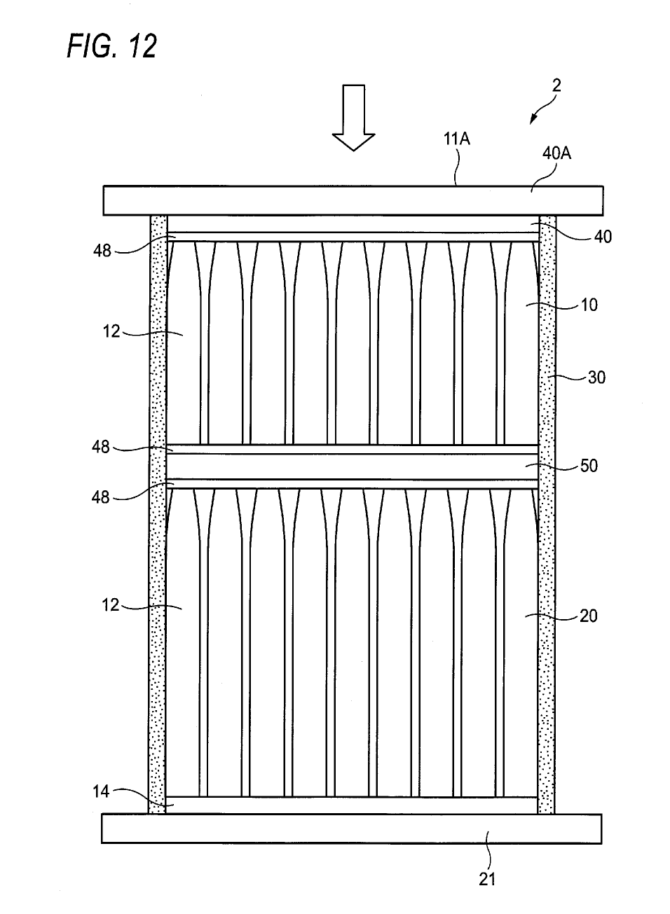

Next, X-ray image detection apparatuses 2 to 4 having a configuration different from the X-ray image detection apparatus 1 shown in FIG. 1 respectively (FIG. 12 to FIG. 14) will be explained hereunder. These X-ray image detection apparatuses 2 to 4 can include the similar configuration to the above detailed configuration of the X-ray image detection apparatus 1, and accordingly can attain the similar operations and effects to those described with regard to the X-ray image detection apparatus 1. Also, various photodetectors and various device materials described later can be adopted in the X-ray image detection apparatuses 2 to 4.

FIG. 12 shows another example of the X-ray image detection apparatus to explain the embodiment of the present invention.

In the X-ray image detection apparatus 1 in FIG. 1, the first scintillator 10 is deposited on the first photodetector 40. In contrast, in the X-ray image detection apparatus 2 in FIG. 12, the first scintillator 10 is deposited on a supporting member (not shown), and then is pasted onto the first photodetector 40.

In manufacturing the X-ray image detection apparatus 2 in FIG. 12, the PDs 41 and the TFTs 42 of the first photodetector 40 are formed on the insulating substrate 40A, and the first scintillator 10 is formed on the supporting member (not shown) made of Al, or the like. Also, the second photodetector 50 is formed on a substrate (not shown) (second photodetector forming step), and the second scintillator 20 is formed on the support 21. The formation of the first and second photodetectors 40, 50 and the first and second scintillators 10, 20 can be carried out irrespective the forming sequence. Then, the first photodetector 40 and the first scintillator 10, the first scintillator 10 and the second photodetector 50, and the second photodetector 50 and the second scintillator 20 are pasted together via an adhesive layer 48 respectively.

As the pasting method in this case, for example, the first photodetector 40 and the first scintillator 10 are pasted together, and then the supporting member (not shown) is peeled off from the first scintillator 10 and is removed (supporting member removing step). When the supporting member is removed in this manner, distortion, damage, etc. of the scintillator caused by a bowing of the supporting member produced at a time of temperature change can be prevented.

Meanwhile, the second photodetector 50 and the second scintillator 20 are pasted together, and then the substrate (not shown) is peeled off from the second photodetector 50 (substrate peeling step). Then, the second photodetector 50 and the first scintillator 10 are pasted together. Thus, the X-ray image detection apparatus 2 is manufactured.

Also, respective steps may be applied as follows. First, the first photodetector 40 and the first scintillator 10 are pasted together, and then the supporting member (not shown) is peeled off from the first scintillator 10 and is removed (supporting member removing step). Then, the first scintillator 10 and the second photodetector 50 are pasted together. Then, the substrate (not shown) is peeled off from the second photodetector 50 (substrate peeling step). Then, the second photodetector 50 and the first scintillator 10 are pasted together, and then the protection film 30 is formed. Thus, the X-ray image detection apparatus 2 is manufactured.

In the X-ray image detection apparatus 2 in FIG. 12, the top end portions of the columnar crystals 12A are arranged on the first photodetector 40 side. Therefore, the crystallinity of the first scintillator 10 on the first photodetector 40 side is improved rather than the configuration in FIG. 1. As shown in FIG. 1, in case the base end portions of the columnar crystals whose crystallinity in the initial phase of the crystal growth is not good are opposed to the first photodetector 40, light absorption caused at the part whose crystallinity is not good is increased. Thus, it is feared that sharpness of the image is degraded. A difference between the crystallinity of the first scintillator 10 in FIG. 1 and the crystallinity of the first scintillator 10 in FIG. 12 is increased by enhancing an activator density in vicinity of the first photodetector 40. In other words, according to the configuration in FIG. 12, MTF can be improved further in contrast to the configuration in FIG. 1.

As described above, the time and labor required for removing the supporting member from the first scintillator 10 are not needed in manufacturing the X-ray image detection apparatus 1 shown in FIG. 1. Therefore, with regard to this respect, the configuration in FIG. 1 is more advantageous than the configuration in FIG. 12.

Also, in the comparison between the X-ray image detection apparatuses 1, 2 in FIG. 1 and FIG. 12, from the viewpoint about how a amount of luminescence in the main luminescence region that is located close to the first photodetector 40 should be increased, the configuration that the top end portions of the columnar crystals 12A whose crystallinity is good are opposed to the second photodetector 50, as shown in FIG. 12, is advantageous.

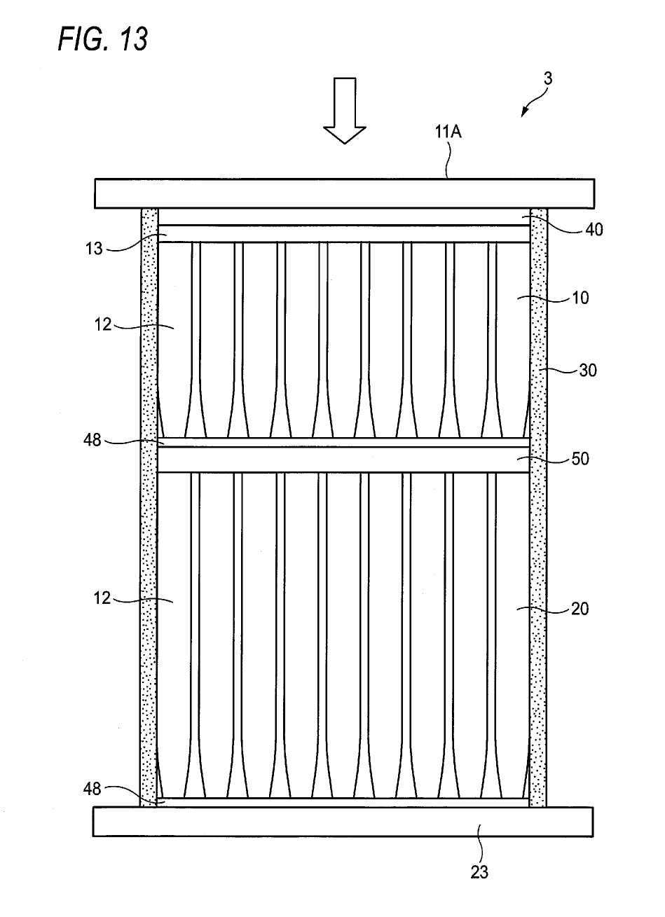

FIG. 13 shows still another example of the X-ray image detection apparatus to explain the embodiment of the present invention.

In the X-ray image detection apparatus 1 in FIG. 1, the second scintillator 20 is pasted on the second photodetector 50. In contrast, in the X-ray image detection apparatus 3 in FIG. 13, the second scintillator 20 is deposited on the second photodetector 50. That is, in the configuration in FIG. 13, both the first and second scintillators 10, 20 are deposited on the photodetector.

In manufacturing the X-ray image detection apparatus 3 in FIG. 13, the TFTs 42 and the PDs 41 of the first photodetector 40 and the first scintillator 10 are formed on the insulating substrate 40A (first photodetector forming step). Also, the second photodetector 50 and the second scintillator 20 are formed in this order on a substrate (not shown) (second photodetector forming step). Then, a supporting member 23 made of Al, plastics, or the like is pasted on the opposite side of the second scintillator 20 to the second photodetector 50 side to support the second scintillator 20, and then the substrate (not shown) is peeled off from the second photodetector 50 (substrate peeling step). Since a distance between the columnar crystals 12A can be maintained by this supporting member 23, it can be prevented that, in peeling off the second photodetector 50 from the substrate, the columnar crystals 12A are brought into contact with each other and are damaged mutually.

Then, the first photodetector 40 and the first scintillator 10, both already integrated, and the second photodetector 50 and the second scintillator 20, both already integrated, are pasted together via the adhesive layer 48, and then the protection film 30 is formed. Thus, the X-ray image detection apparatus 3 is manufactured. Here, the supporting member 23 may be removed after the first scintillator 10 and the second scintillator 20 are pasted together. In this case, when the supporting member 23 is made of Al, or the like, such supporting member 23 serves as a reflecting member for the lights that are generated by the second scintillator 20. An amount of luminescence of the lights that are incident on the second photodetector 50 can be increased due to the light reflection by the supporting member 23.

In comparison of the X-ray image detection apparatuses 1, 3 in FIG. 1 and FIG. 13, the configuration in FIG. 1 is advantageous in such a respect that the use of the supporting member 23 at a time of peeling the substrate from the second photodetector 50 is not needed.

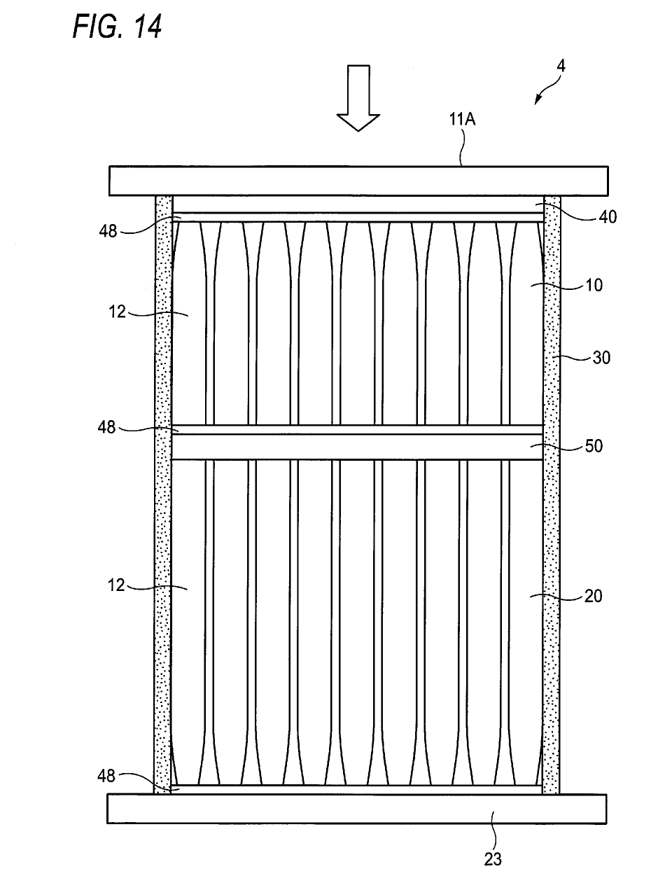

FIG. 14 shows yet another example of the X-ray image detection apparatus to explain the embodiment of the present invention. In the X-ray image detection apparatus 4 in FIG. 14, the first scintillator 10 is pasted on the first photodetector 40 like the first scintillator 10 in FIG. 12, and also is pasted on the second photodetector 50 like the second scintillator 20 in FIG. 13.

In manufacturing the X-ray image detection apparatus 4 in FIG. 14, the PDs 41 and the TFTs 42 of the first photodetector 40 are formed on the insulating substrate 40A, and then the first scintillator 10 is formed on the supporting member (not shown). The first photodetector 40 and the first scintillator 10 are pasted together, and then the supporting member (not shown) is peeled off from the first scintillator 10 and is removed (supporting member removing step). Also, the second photodetector 50 and the second scintillator 20 are formed in this order on the substrate (not shown) (second photodetector forming step).

Then, the supporting member 23 is pasted on the second scintillator 20 on the opposite side to the second photodetector 50 side to support the second scintillator 20, and then the substrate (not shown) is peeled off from the second photodetector 50 (substrate peeling step). Then, the first photodetector 40 and the first scintillator 10, both already pasted integrally, and the second photodetector 50 and the second scintillator 20, both already integrated, are pasted together via the adhesive layer 48, and then the protection film 30 is formed. Thus, the X-ray image detection apparatus 4 is manufactured. Here, the supporting member 23 may be removed after the first scintillator 10 and the second scintillator 20 are pasted together. In this case, when the supporting member 23 is made of Al, or the like, such supporting member 23 serves as a reflecting member for the lights that are generated by the second scintillator 20. An amount of luminescence of the lights that are incident on the second photodetector 50 can be increased due to the light reflection by the supporting member 23.

In the X-ray image detection apparatus 4 in FIG. 14, the top end portions of the columnar crystals 12A of the first scintillator 10 are opposed to the first photodetector 40, like the X-ray image detection apparatus 1 in FIG. 1. Therefore, as described above, while suppressing the disorder of the crystallinity, an amount of luminescence can be increased by enhancing the activator density at the top end portions of the columnar crystals 12A.

In the comparison between the X-ray image detection apparatuses 1, 4 in FIG. 1 and FIG. 14, the configuration in FIG. 1 is advantageous in such a respect that the use of the supporting member 23 at a time of peeling the substrate from the second photodetector 50 is not needed.

Also, the activator density distributions of the first and second scintillators shown in FIG. 7A to FIG. 11B are applicable to the X-ray image detection apparatuses 2 to 4 in FIG. 12 to FIG. 14. Also, the activator density distributions in FIG. 7A to FIG. 11B may be combined with each other.

In respective the X-ray image detection apparatuses in FIG. 1, FIG. 12 to FIG. 14, the non-columnar portions such as the non-columnar portions 13, 14 containing the non-columnar crystals may not be formed. In this case, following advantages can be achieved by forming the non-columnar portion. This non-columnar portion can be formed in any positions of the first and second scintillators respectively.

In case the non-columnar portion is formed at the base end portions or the top end portions of the first and second scintillators in the crystal growth direction respectively, the adhesion to the support or the photodetector that is pasted on the first and second scintillators respectively, or the adhesion to the substrate on which the first and second scintillators are deposited respectively can be ensured. According to the insurance of adhesion, the peeing from the support or the photodetector can be prevented, and the performance degradation caused due to moisture absorption of the scintillator can be prevented. Also, when the non-columnar portion is formed on the top end side of the columnar crystals 12A, the surface of the scintillator is planarized by the non-columnar portion. Therefore, the scintillator and the photodetector can be adhered uniformly together. Accordingly, a picture quality of the detected image can be uniformized.

Also, strength of the top end of the scintillator can be improved by forming the non-columnar portions at the end portions of the columnar portions. Accordingly, not only an impact resistance can be improved, but also strength to the load applied when the scintillator is pasted on the support or the photodetector can be ensured. Therefore, the scintillator can be pressed strongly against the photodetector, or the like, and thus both members can be adhered uniformly. Further, a load capacity of the scintillator can be increased by ensuring the strength of the scintillator, and thus the scintillator can be used by pasting on the roof of the apparatus housing. At this time, since the substrate is peeled off from the second photodetector, respective photodetectors can be positioned very close to the roof, and the effects of improvement of the sensitivity and the picture quality can be increased much more. Here, an inflow of the protection film material into clearances between the columnar crystals can be prevented by forming the non-columnar portion on the top end portions of the columnar portions. Therefore, the effect of suppressing the degradation of MTF can also be obtained.

Also, when the non-columnar portion is formed at the base end portions (the portions formed in the initial phase of the vapor deposition) of the scintillator, the columnar crystals 12A can be grown with good crystallinity on a basis of the non-columnar portion.

In response to a diameter, a thickness, a void ratio, etc. of the non-columnar crystals, the reflecting characteristics may be given to the non-columnar portion. In an example in FIG. 1, because the non-columnar portion 14 is provided to the end portion of the second scintillator 20 on the support 21 side, an amount of luminescence of the lights that are incident on the second photodetector 50 can be increased.

### [7. Variations of Photodetector]

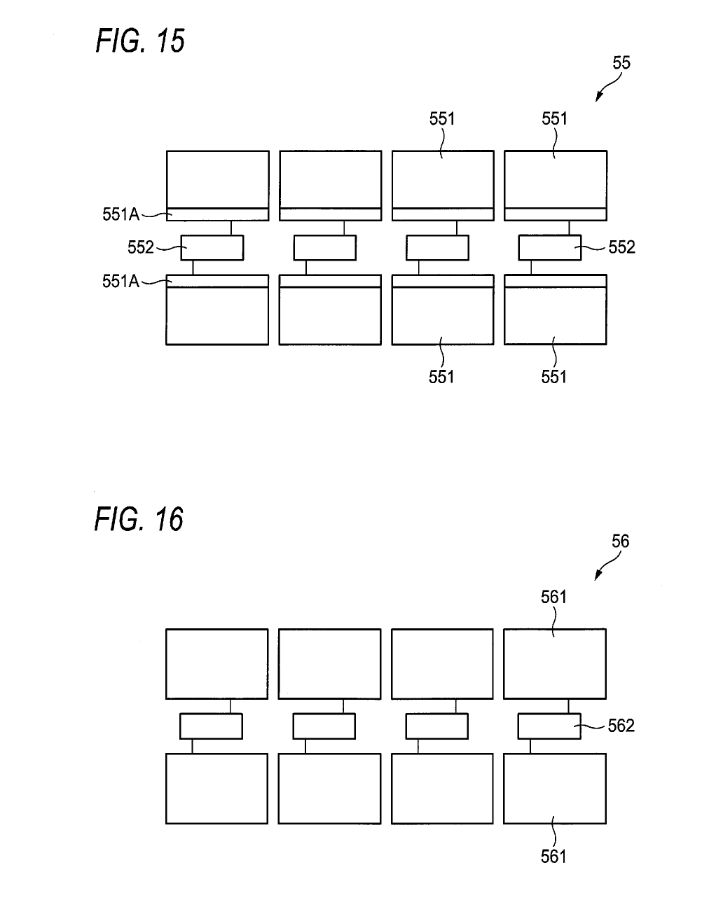

FIG. 15 shows another second photodetector 55 that can be replaced with the second photodetector 50 shown in FIG. 2. The second photodetector 55 includes a plurality of TFTs 552 each of which is assigned to one pixel, and a plurality of PDs 551 two of which are arranged on both sides of the TFT 552 in the thickness direction respectively, and is constructed by stacking the PDs 551, the TFTs 552, and the PDs 551. Because the PDs 551 and the TFTs 552 are stacked in this manner, a distance between the first and second scintillators on both sides of the second photodetector 55 can be shortened. The distance between the first and second scintillators is kept less than 40 μm, as described above.

In the configuration in FIG. 2, the PDs 51 and the TFTs 52 are arranged on the same plane or the substantially same plane, and the lights are incident on each of the PDs 51 from both the first and second scintillators 10, 20. In contrast, in the configuration in FIG. 15, each of the PDs 551, 551 is provided in the X-ray traveling direction on both sides of the TFT 552, and therefore the lights emitted from the first scintillator are incident on one PD 551 provided on the first scintillator side whereas the lights emitted from the second scintillator are incident on the other PD 551. Because the PD 551 in FIG. 15 can keep a light receiving surface more widely than the PD 51 in FIG. 2, an amount of incident light on the PD can be increased and also a light collecting efficiency can be improved.

Also, each of the PDs 551, 551 has a light reflecting layer 551A on the TFT 552 side, and accordingly a switching noise of the TFT 552 can be reduced.

Also, the TFT formed of an amorphous oxide semiconductor (a-IGZO) can be used in both the second photodetector 50 in FIG. 2 and the second photodetector 55 in FIG. 15. The a-IGZO has a sensitivity in a wavelength of 350 nm or more, and the a-IGZO seldom has a sensitivity in the visible light range. Thus, the light reflecting layer can be neglected.

Also, the organic material can be employed as the PD and the TFT. FIG. 16 shows photoelectric conversion elements 561 each formed of the OPC (organic photoelectric material), and TFTs 562 each formed of the organic material. The second photodetector 50 shown in FIG. 2 can also be replaced with second photodetector 56 that has the photoelectric conversion elements 561 and the TFTs 562.

The X-ray absorption is hardly caused by the organic material used as the photoelectric conversion elements 561 and the TFTs 562. Therefore, an amount of X rays that pass through the photoelectric conversion elements 561 and the TFT 562 and reach the second scintillator can be increased. Here, in the case where the CsI:Tl that emits green lights is used as the scintillator, quinacrine is used as the OPC of the photoelectric conversion elements 561, and the transparent organic material of the TFT is formed of a phthalocyanine compound in Chemical Formula 1, a naphthalocyanine compound in Chemical Formula 2, or the like set forth in JP-A-2009-212389, for example, the switching noise of the TFT is seldom produced even when the light reflecting layer is not provided unlike FIG. 16. When the light reflecting layer is not provided, in some cases the lights leak out from the photoelectric conversion elements 561 arranged on the first scintillator side to the second scintillator side. In this event, since most of the leaked lights are incident on the photoelectric conversion elements 561 that correspond to the same pixels on the second scintillator side, no problem arises.

In FIG. 16, an example in which the photoelectric conversion element 561 is arranged on both sides of the TFT respectively is illustrated. As shown in FIG. 2, the photoelectric conversion elements 561 and the TFTs 562 may be arranged on the same plane or the substantially same plane.

### [8. Energy Subtraction Photographic Panel]

By the way, an energy subtraction photographic panel can be constructed by using two scintillators. In this case, the first and second scintillators are constructed by the fluorescent materials whose sensitivity (K absorption edge and emission wavelength) to the radiation X is different mutually. Concretely, the first scintillator picks up a low voltage image of the soft parts tissue that is represented by a low energy radiation out of the radiations that passed through the subject. Hence, the first scintillator is constructed by the fluorescent material whose radiation absorptance μ has no K absorption edge in the high energy part, i.e., whose radiation absorptance μ is never increased discontinuously in the high energy part. Also, the second scintillator picks up a high voltage image of a hard parts tissue that is represented by a high energy radiation out of the radiations that passed through the subject. Hence, the second scintillator is constructed by the fluorescent material whose radiation absorptance μ is made higher than the fluorescent material used in the first scintillator in the high energy part.

Here, the “soft parts tissue” contains muscles, internal organs, etc., and denotes the tissue other than bone tissues such as a cortical bone and/or a sponge bone, etc. Also, the “hard parts tissue” is called a hard tissue, and denotes the bone tissue such as a cortical bone and/or a sponge bone, etc.

The fluorescent materials used as the first and second scintillators respectively can be appropriately chosen from all materials that are commonly used as the scintillator if the fluorescent materials have different sensitivities to the radiation energy mutually. For example, the materials can be chosen from the fluorescent materials listed in a Table 1 given hereunder. In this case, from the viewpoint that a distinction between the low voltage image and the high voltage image being obtained by the photography is made clear, it is preferable that the fluorescent materials used as the first and second scintillators respectively should be different not only in the sensitivity to the radiation but also in the luminous color mutually.

TABLE 1

| | Luminous | | K absorption |
|---|---|---|---|
| Composition | color | Wavelength [nm] | end [eV] |
| HfP₂O₇ | ultraviolet | 300 | 65.3 |
| YtaO₄ | ultraviolet | 340 | 67.4 |
| BaSO₄:Eu | violet | 375 | 37.4 |
| BaFCl:Eu | violet | 385 | 37.4 |
| BaFBr:Eu | violet | 390 | 37.4 |
| YtaO₄:Nb | blue | 410 | 67.4 |
| CsI:Na | blue | 420 | 36/33.2 |
| CaWO₄ | blue | 425 | 69.5 |
| ZnS:Ag | blue | 450 | 9.7 |
| LaOBr:Tm | blue | 460 | 38.9 |
| Bi₄Ge₃O₁₂ | blue | 480 | 90.4 |
| CdSO₄ | bluish green | 480 | 27/69.5 |
| LaOBr:Tb | bluish white | 380, 415, 440, 545 | 38.9 |
| Y₂O₂S:Tb | bluish white | 380, 415, 440, 545 | 17.03 |
| Gd₂O₂S:Pr | green | 515 | 50.2 |
| (Zn,Cd)S:Ag | green | 530 | 9.7/27 |
| CsI:Tl | green | 540 | 36/33.2 |
| Gd₂O₂S:Tb | green | 545 | 60.2 |
| La₂O₂S:Tb | green | 545 | 38.9 |

Here, in addition to the fluorescent materials in Table 1, CsBr:Eu, ZnS:Cu, Gd₂O₂S:Eu, Lu₂O₂S:Tb, etc. can be chosen.

In this case, from the viewpoint that high picture quality can be obtained, it is preferable that the fluorescent material whose base material constituting the columnar structure is formed of CsI or CsBr should be chosen from the above. In particular, the high picture quality that enables the fine parts of the soft parts tissue to represent satisfactorily is required of the low voltage image. Therefore, it is more preferable that the first scintillator should be formed of the fluorescent material that allows the first scintillator to get the columnar structure. Concretely, when the first scintillator is formed to have the columnar structure, the lights being converted by the first scintillator can travel through the columnar structure while reflecting at the boundaries between the columnar structures, and thus the light scattering can be reduced. Accordingly, an amount of received light of the PD 51 is increased, and hence the low voltage image of high picture quality can be obtained.

Also, from the viewpoint that no noise should be produced in the picked-up radiographic image without the provision of the color filter that absorbs the lights having a predetermined wavelength (shields the lights), the fluorescent material that emits the light having a not-broad and sharp wavelength (luminous wavelength is narrow) is preferable among the above materials, except CsI:Tl, (Zn,Cd)S:Ag, CaWO₄:Pb, La₂Obr:Tb, ZnS:Ag, and CsI:Na. As the fluorescent material that emits the light having such sharp wavelength, for example, Gd₂O₂S:Tb and La₂O₂S:Tb both emitting the green light, and BaFX:Eu emitting the blue light (where, X denotes a halogen element such as Br, Cl, or the like) can be listed. Among them, particularly a combination of the BaFX:Eu emitting the blue light and the Gd₂O₂S:Tb emitting the green light is preferable, as a combination of the fluorescent materials used in the first and second scintillators.

When the energy subtraction photographic panel is constructed, the photodetector (e.g., the PD and the TFT) is provided to every first and second scintillators between the first and second scintillators. Then, in order to avoid such a situation that respective emitted lights of the first and second scintillators are mixed, a light shielding layer is provided between the PDs of the first scintillators and the PDs of the second scintillator.

Here, in the first and second scintillators used in the energy subtraction photographic panel, the similar advantages to those mentioned above can be achieved by providing the above configuration, e.g., the configuration that relates to the change of the activator density. When the above X-ray image detection apparatus is constructed as the energy subtraction photographic panel, both the low voltage image of the soft parts tissue, which is represented by the radiation of low energy out of the radiation that passed through the subject, and the high voltage image of the hard parts tissue, which is represented by the radiation of high energy, can be detected with high precision.

### [9. Available Device Material]

### [9-1. OPC (Organic Photoelectric Conversion) Material]

For example, any OPC (Organic Photoelectric Conversion) material disclosed in JP-A-2009-32854 can be used for the aforementioned PDs 51 (FIG. 2). A film formed out of the OPC material (hereinafter referred to as OPC film) can be used as the photoconductive layer 410 of the PDs 51. The OPC film contains an organic photoelectric conversion material, which absorbs light emitted from the scintillator and generates electric charges corresponding to the absorbed light. Thus, the OPC film containing the organic photoelectric conversion material has a sharp absorption spectrum in a visible light range. Electromagnetic waves other than the light emitted by the scintillator are hardly absorbed by the OPC film. Thus, noise generated by radioactive rays such as X-rays absorbed by the OPC film can be suppressed effectively.

It is preferable that the absorption peak wavelength of the organic photoelectric conversion material forming the OPC film is closer to the peak wavelength of light emitted by the scintillator in order to more efficiently absorb the light emitted by the scintillator. Ideally, the absorption peak wavelength of the organic photoelectric conversion material agrees with the peak wavelength of the light emitted by the scintillator. However, if the difference between the absorption peak wavelength of the organic photoelectric conversion material and the peak wavelength of the light emitted by the scintillator is small, the light emitted by the scintillator can be absorbed satisfactorily. Specifically, the difference between the absorption peak wavelength of the organic photoelectric conversion material and the peak wavelength of the light emitted by the scintillator in response to radioactive rays is preferably not larger than 10 nm, more preferably not larger than 5 nm.

Examples of the organic photoelectric conversion material that can satisfy such conditions include arylidene-based organic compounds, quinacridone-based organic compounds, and phthalocyanine-based organic compounds. For example, the absorption peak wavelength of quinacridone in a visible light range is 560 nm. Therefore, when quinacridone is used as the organic photoelectric conversion material and CsI(Tl) is used as the fluorescent material, the aforementioned difference in peak wavelength can be set within 5 nm so that the amount of electric charges generated in the OPC film can be increased substantially to the maximum.

At least a part of an organic layer provided between the bias electrode and the charge collection electrode of PD 51 can be formed out of an OPC film. More specifically, the organic layer can be formed out of a stack or a mixture of a portion for absorbing electromagnetic waves, a photoelectric conversion portion, an electron transport portion, an electron hole transport portion, an electron blocking portion, an electron hole blocking portion, a crystallization prevention portion, electrodes, interlayer contact improvement portions, etc.

Preferably the organic layer contains an organic p-type compound or an organic n-type compound. An organic p-type semiconductor (compound) is a donor-type organic semiconductor (compound) as chiefly represented by an electron hole transport organic compound, meaning an organic compound having characteristic to easily donate electrons. More in detail, of two organic materials used in contact with each other, one with lower ionization potential is called the donor-type organic compound. Therefore, any organic compound may be used as the donor-type organic compound as long as the organic compound having characteristic to donate electrons. Examples of the donor-type organic compound that can be used include a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyarylene compound, a fused aromatic carbocyclic compound (naphthalene derivative, anthracene derivative, phenanthrene derivative, tetracene derivative, pyrene derivative, perylene derivative, fluoranthene derivative), a metal complex having a nitrogen-containing heterocyclic compound as a ligand, etc. The donor-type organic semiconductor is not limited thereto but any organic compound having lower ionization potential than the organic compound used as an n-type (acceptor-type) compound may be used as the donor-type organic semiconductor.

The n-type organic semiconductor (compound) is an acceptor-type organic semiconductor (compound) as chiefly represented by an electron transport organic compound, meaning an organic compound having characteristic to easily accept electrons. More specifically, when two organic compounds are used in contact with each other, one of the two organic compounds with higher electron affinity is the acceptor-type organic compound. Therefore, any organic compound may be used as the acceptor-type organic compound as long as the organic compound having characteristic to accept electrons. Examples thereof include a fused aromatic carbocyclic compound (naphthalene derivative, anthracene derivative, phenanthrene derivative, tetracene derivative, pyrene derivative, perylene derivative, fluoranthene derivative), a 5- to 7-membered heterocyclic compound containing a nitrogen atom, an oxygen atom or a sulfur atom (e.g. pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyralidine, pyrrolopyridine, thiadiazolopyridine, dibenzazepine, tribenzazepine etc.), a polyarylene compound, a fluorene compound, a cyclopentadiene compound, a silyl compound, and a metal complex having a nitrogen-containing heterocyclic compound as a ligand. The acceptor-type organic semiconductor is not limited thereto. Any organic compound may be used as the acceptor-type organic semiconductor as long as the organic compound has higher electron affinity than the organic compound used as the donor-type organic compound.

As for p-type organic dye or n-type organic dye, any known dye may be used. Preferred examples thereof include cyanine dyes, styryl dyes, hemicyanine dyes, merocyanine dyes (including zero-methine merocyanine (simple merocyanine)), trinuclear merocyanine dyes, tetranuclear merocyanine dyes, rhodacyanine dyes, complex cyanine dyes, complex merocyanine dyes, alopolar dyes, oxonol dyes, hemioxonol dyes, squarylium dyes, croconium dyes, azamethine dyes, coumarin dyes, arylidene dyes, anthraquinone dyes, triphenylmethane dyes, azo dyes, azomethine dyes, spiro compounds, metallocene dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dyes, metal complex dyes, and fused aromatic carbocyclic dyes (naphthalene derivative, anthracene derivative, phenanthrene derivative, tetracene derivative, pyrene derivative, perylene derivative, fluoranthene derivative).

A photoelectric conversion film (photosensitive layer) which has a layer of a p-type semiconductor and a layer of an n-type semiconductor between a pair of electrodes and at least one of the p-type semiconductor and the n-type semiconductor is an organic semiconductor and in which a bulk heterojunction structure layer including the p-type semiconductor and the n-type semiconductor is provided as an intermediate layer between those semiconductor layers may be used preferably. The bulk heterojunction structure layer included in the photoelectric conversion film can cover the defect that the carrier diffusion length of the organic layer is short. Thus, the photoelectric conversion efficiency can be improved. The bulk heterojunction structure has been described in detail in JP-A-2005-303266.

It is preferable that the photoelectric conversion film is thicker in view of absorption of light from the scintillator. The photoelectric conversion film is preferably not thinner than 30 nm and not thicker than 300 nm, more preferably not thinner than 50 nm and not thicker than 250 nm, particularly more preferably not thinner than 80 nm and not thicker than 200 nm in consideration of the ratio which does make any contribution to separation of electric charges.

As for any other configuration about the aforementioned OPC film, for example, refer to description in JP-A-2009-32854.

### [9-2. Organic TFT (Thin Film Transistor)]

Although inorganic materials are often used for the aforementioned TFTs 52, organic materials may be used, for example, as disclosed in JP-A-2009-212389. Organic TFT may have any type of structure but a field effect transistor (FET) structure is the most preferable. In the FET structure, a substrate is disposed in the bottom layer, and a gate electrode is provided partially an upper surface of the substrate. An insulator layer is provided to cover the electrode and touch the substrate in the other portion than the electrode. Further, a semiconductor active layer is provided on an upper surface of the insulator layer, and a source electrode and a drain electrode are disposed partially on the upper surface of the semiconductor active layer and at a distance from each other. This configuration is called a top contact type device. A bottom contact type device in which a source electrode and a drain electrode are disposed under a semiconductor active layer may be also used preferably. In addition, a vertical transistor structure in which a carrier flows in the thickness direction of an organic semiconductor film may be used.

### (Semiconductor Active Layer)

A p-type organic semiconductor material is used as the material of the semiconductor active layer. The p-type organic semiconductor material is substantially colorless and transparent. For example, the thickness of the organic semiconductor thin film may be measured by a stylus thickness meter. A plurality of thin films with different thicknesses may be manufactured and their absorption spectra may be measured so that the maximum absorbance per film thickness of 30 nm can be obtained by conversion based on a calibration curve.

Organic semiconductor materials mentioned herein are organic materials showing properties as semiconductors. Examples of the organic semiconductor materials include p-type organic semiconductor materials (or referred to as p-type materials simply or as electron hole transport materials) which conduct electron holes (holes) as carriers, and n-type organic semiconductor materials (or referred to as n-type materials simply or as electrode transport materials) which conduct electrons as carriers, similarly to a semiconductor formed out of an inorganic material. Of the organic semiconductor materials, lots of p-type materials generally show good properties. In addition, p-type transistors are generally excellent in operating stability as transistors under the atmosphere. Here, description here will be made on a p-type organic semiconductor material.

One of properties of organic thin film transistors is a carrier mobility (also referred to as mobility simply) μ which indicates the mobility of a carrier in an organic semiconductor layer. Although preferred mobility varies in accordance with applications, higher mobility is generally preferred. The mobility is preferably not lower than 1.0*10⁻⁷ cm²/Vs, more preferably not lower than 1.0*10⁻⁶ cm²/Vs, further preferably not lower than 1.0*10⁻⁵ cm²/Vs. The mobility can be obtained by properties or TOF (Time Of Flight) measurement when the field effect transistor (FET) device is manufactured.

The p-type organic semiconductor material may be either a low molecular weight material or a high molecular weight material, but preferably a low molecular weight material. Lots of low molecular weight materials typically show excellent properties due to easiness in high purification because various refining processes such as sublimation refining, recrystallization, column chromatography, etc. can be applied thereto, or due to easiness in formation of a highly ordered crystal structure because the low molecular weight materials have a fixed molecular structure. The molecular weight of the low molecular weight material is preferably not lower than 100 and not higher than 5,000, more preferably not lower than 150 and not higher than 3,000, further more preferably not lower than 200 and not higher than 2,000.

Preferred specific examples of such a p-type organic semiconductor material will be shown. Bu represents a butyl group, Pr represents a propyl group, Et represents an ethyl group, and Ph represents a phenyl group.

[Chemical 1]

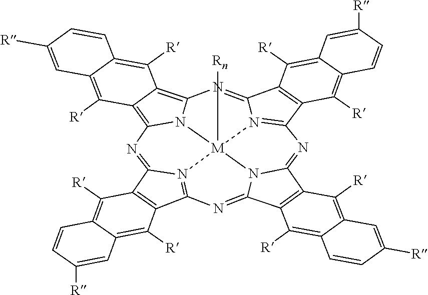

Compound 1 to 15

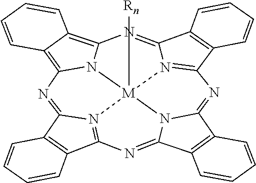

Compound 16 to 20

| Compound | M | R | n | R′ | R″ |
|---|---|---|---|---|---|
| 1 | Si | OSi(n-Bu)₃ | 2 | H | H |
| 2 | Si | OSi(i-Pr)₃ | 2 | H | H |
| 3 | Si | OSi(OEt)₃ | 2 | H | H |
| 4 | Si | OSiPh₃ | 2 | H | H |
| 5 | Si | O(n-C₈H₁₇) | 2 | H | H |
| 7 | Ge | OSi(n-Bu)₃ | 2 | H | H |
| 8 | Sn | OSi(n-Bu)₃ | 2 | H | H |
| 9 | Al | OSi(n-C₆H₁₃)₃ | 1 | H | H |
| 10 | Ga | OSi(n-C₆H₁₃)₃ | 1 | H | H |
| 11 | Cu | — | — | O(n-Bu) | H |
| 12 | Ni | — | — | O(n-Bu) | H |
| 13 | Zn | — | — | H | t-Bu |
| 14 | V═O | — | — | H | t-Bu |
| 15 | H₂ | — | — | H | t-Bu |
| 16 | Si | OSiEt₃ | 2 | — | — |
| 17 | Ge | OSiEt₃ | 2 | — | — |
| 18 | Sn | OSiEt₃ | 2 | — | — |
| 19 | Al | OSiEt₃ | 1 | — | — |
| 20 | Ga | OSiEt₃ | 1 | — | — |

### (Device Constituent Materials Other Than Semiconductor Active Layer)

Description will be made below on device constituent materials other than the semiconductor active layer in the organic thin film transistor. The visible-light or infrared-light transmittance of each of those materials is preferably not lower than 60%, more preferably not lower than 70%, further more preferably not lower than 80%.

The substrate is not limited particularly as long as it has required smoothness. Examples of the substrate include glass, quartz, light transmissive plastic film, etc. Examples of the light transmissive plastic film include films or the like, made from polyethylene terephthalate (PET), polyethylene naphthalate (PEN), polyether sulfone (PES), polyether imide, polyetheretherketone, polyphenylene sulfide, polyalylate, polyimide, polycarbonate (PC), cellulose triacetate (TAC), cellulose acetate propionate (CAP), etc. In addition, any organic or inorganic filler may be contained in these plastic films. A flexible substrate formed out of aramid, bionanofiber, or the like may be used preferably as the substrate.

The material forming the gate electrode, the source electrode or the drain electrode is not limited especially if it has required electric conductivity. Examples thereof include electrically conductive oxides such as ITO (indium-doped tin oxide), IZO (indium-doped zinc oxide), SnO₂, ATO (antimony-doped tin oxide), ZnO, AZO (aluminum-doped zinc oxide), GZO (gallium-doped zinc oxide), TiO₂, FTO (fluorine-doped tin oxide), etc., electrically conductive polymers such as PEDOT/PSS (poly(3,4-ethylenedioxythiophene)/polystyrenesulfonate), carbon materials such as carbon nanotube, etc. These electrode materials may be formed into films, for example, by a method such as a vacuum deposition method, sputtering, a solution application method, etc.

The material used for the insulating layer is not limited particularly as long as it has required insulating effect. Examples thereof include inorganic materials such as silicon dioxide, silicon nitride, alumina, etc., and organic materials such as polyester, (PEN (polyethylene naphthalate), PET (polyethylene terephthalate) etc.), polycarbonate, polyimide, polyamide, polyacrylate, epoxy resin, polyparaxylylene resin, novolak resin, PVA (polyvinyl alcohol), PS (polystyrene), etc. These insulating film materials may be formed into films, for example, by a method such as a vacuum deposition method, sputtering, a solution application method, etc.

As for any other configuration about the aforementioned organic TFT, for example, refer to description in JP-A-2009-212389.

### [9-3. Amorphous Oxide Semiconductor]

For example, amorphous oxide disclosed in JP-A-2010-186860 may be used for the aforementioned TFTs 52. Here, description will be made on an amorphous oxide containing active layer of a FET transistor disclosed in JP-A-2010-186860. The active layer serves as a channel layer of the FET transistor where electrons or holes move.

The active layer has a configuration containing an amorphous oxide semiconductor. The amorphous oxide semiconductor can be formed into a film at a low temperature. Thus, the amorphous oxide semiconductor is formed preferably on a flexible substrate.

The amorphous oxide semiconductor used for the active layer is preferably amorphous oxide containing at least one kind of element selected from a group consisting of In, Sn, Zn and Cd, more preferably amorphous oxide containing at least one kind of element selected from a group consisting of In, Sn and Zn, further preferably amorphous oxide containing at least one kind of element selected from a group consisting of In and Zn.

Specific examples of the amorphous oxide used for the active layer include In₂O₃, ZnO, SnO₂, CdO, Indium-Zinc-Oxide (IZO), Indium-Tin-Oxide (ITO), Gallium-Zinc-Oxide (GZO), Indium-Gallium-Oxide (IGO), and Indium-Gallium-Zinc-Oxide (IGZO).

It is preferable that a vapor phase film formation method targeting at a polycrystal sinter of the oxide semiconductor is used as a method for forming the active layer. Of vapor phase film formation methods, a sputtering method or a pulse laser deposition (PLD) method is preferred. Further, the sputtering method is preferred in view from mass productivity. For example, the active layer is formed by an RF magnetron sputtering deposition method with a controlled degree of vacuum and a controlled flow rate of oxygen.

The thus formed active layer is confirmed to be an amorphous film by a well-known X-ray diffraction method. The composition ratio of the active layer is obtained by an RBS (Rutherford Backscattering Spectrometry) method.

In addition, the electric conductivity of the active layer is preferably lower than 10² Scm⁻¹ and not lower than 10⁻⁴ Scm⁻¹, more preferably lower than 10² Scm⁻¹ and not lower than 10⁻¹ Scm⁻¹. Examples of the method for adjusting the electric conductivity of the active layer include a known adjusting method using oxygen defect, an adjusting method using a composition ratio, an adjusting method using impurities, and an adjusting method using an oxide semiconductor material.

As for any other configuration about the aforementioned amorphous oxide, for example, refer to description in JP-A-2010-186860.

### [9-4. Flexible Material]

It may be considered that aramid, bionanofiber, etc. having properties such as flexibility, low thermal expansion and high strength, which cannot be obtained in existing glass or plastic, are used in a radiological image detection apparatus.

### (1) Aramid

A film (or a sheet or a substrate) formed out of aramid which is a flexible material may be used as the support 101, the circuit board of the control module, or the like. An aramid material has high heat resistance showing a glass transition temperature of 315° C., high rigidity showing a Young's modulus of 10 GPa, and high dimensional stability showing a thermal expansion coefficient of −3 to 5 ppm/° C. Therefore, when a film made from aramid is used, it is possible to easily form a high-quality film for a semiconductor layer or a scintillator, as compared with the case where a general resin film is used. In addition, due to the high heat resistance of the aramid material, a transparent electrode material can be cured at a high temperature to have low resistance. Further, it is also possible to deal with automatic mounting with ICs, including a solder reflow step. Furthermore, since the aramid material has a thermal expansion coefficient close to that of ITO (indium tin oxide), a gas barrier film or a glass substrate, warp after manufacturing is small. In addition, cracking hardly occurs. Here, it is preferable to use a halogen-free (in conformity with the requirements of JPCA-ES01-2003) aramid material containing no halogens, in view of reduction of environmental load.

The aramid film may be laminated with a glass substrate or a PET substrate, or may be pasted onto a housing of a device.

High intermolecular cohesion (hydrogen bonding force) of aramid leads to low solubility to a solvent. When the problem of the low solubility is solved by molecular design, an aramid material easily formed into a colorless and transparent thin film can be used preferably. Due to molecular design for controlling the order of monomer units and the substituent species and position on an aromatic ring, easy formation with good solubility can be obtained with the molecular structure kept in a bar-like shape with high linearity leading to high rigidity or dimensional stability of the aramid material. Due to the molecular design, halogen-free can be also achieved.

In addition, an aramid material having an optimized characteristic in an in-plane direction of a film can be used preferably. Tensional conditions are controlled in each step of solution casting, vertical drawing and horizontal drawing in accordance with the strength of the aramid film which varies constantly during casting. Due to the control of the tensional conditions, the in-plane characteristic of the aramid film which has a bar-like molecular structure with high linearity leading to easy occurrence of anisotropic physicality can be balanced.

Specifically, in the solution casting step, the drying rate of the solvent is controlled to make the in-plane thickness-direction physicality isotropic and optimize the strength of the film including the solvent and the peel strength from a casting drum. In the vertical drawing step, the drawing conditions are controlled precisely in accordance with the film strength varying constantly during drawing and the residual amount of the solvent. In the horizontal drawing, the horizontal drawing conditions are controlled in accordance with a change in film strength varying due to heating and controlled to relax the residual stress of the film. By use of such an aramid material, the problem that the aramid film after casting may be curled.

In each of the contrivance for the easiness of casting and the contrivance for the balance of the film in-plane characteristic, the bar-like molecular structure with high linearity peculiar to aramid can be kept to keep the thermal expansion coefficient low. When the drawing conditions during film formation are changed, the thermal expansion coefficient can be reduced further.

### (2) Bionanofiber

Components sufficiently small relative to the wavelength of light produce no scattering of the light. Accordingly, a flexible plastic material, or the like, reinforced by nanofibers may be used preferably in the insulating substrate 40A, the circuit board of the control module, or the like. Of the nanofibers, a composite material (occasionally referred to as bionanofiber) of bacterial cellulose and transparent resin can be used preferably. The bacterial cellulose is produced by bacteria (Acetobacter Xylinum). The bacterial cellulose has a cellulose microfibril bundle width of 50 nm, which is about 1/10 as large as the wavelength of visible light. In addition, the bacterial cellulose is characterized by high strength, high elasticity and low thermal expansion.

When a bacterial cellulose sheet is impregnated with transparent resin such as acrylic resin or epoxy resin and hardened, transparent bionanofiber showing a light transmittance of about 90% in a wavelength of 500 nm while having a high fiber ratio of about 60 to 70% can be obtained. By the bionanofiber, a thermal expansion coefficient (about 3 to 7 ppm) as low as that of silicon crystal, strength (about 460 MPa) as high as that of steel, and high elasticity (about 30 GPa) can be obtained.

As for the configuration about the aforementioned bionanofiber, for example, refer to description in JP-A-2008-34556.

The aforementioned X-ray image detection apparatus 1 can be incorporated and used in various systems such as a medical X-ray imaging system. Particularly, the X-ray image detection apparatus 1 in this example having characteristics of high sensitivity and high definition can be preferably used in mammography equipment required to detect a sharp image with a low dose of radiation.

In addition to the medical X-ray imaging system, for example, the X-ray image detection apparatus 1 is also applicable to an industrial X-ray imaging system for nondestructive inspection, or a system for detecting particle rays (α-rays, β-rays, γ-rays) other than electromagnetic waves. The X-ray image detection apparatus 1 has a wide range of applications.

### [10. Disclosure of Specification]

It is disclosed a radiological image detection apparatus including: a first scintillator and a second scintillator that emit fluorescent lights in response to irradiation of radiation; and a first photodetector and a second photodetector that detect the fluorescent lights; in which the first photodetector, the first scintillator, the second photodetector, and the second scintillator are arranged in order from a radiation incident side, and a high activator density region in which an activator density is relatively higher than an average activator density in a concerned scintillator is provided to at least one of the first scintillator located in vicinity of the first photodetector and the second scintillator located in vicinity of the second photodetector.

In the radiological image detection apparatus, the second photodetector may be provided by forming the second photodetector on a substrate, and peeling off the second photodetector from the substrate.

In the radiological image detection apparatus, a high activator density region in which an activator density is relatively higher than an average activator density in the first scintillator may be provided to the first scintillator located in vicinity of the second photodetector.

In the radiological image detection apparatus, the high activator density region may be provided to the first scintillator located in vicinity of the first photodetector; and a low activator density region in which in which an activator density is relatively lower than an average activator density in the first scintillator may be provided between the high activator density region in the first scintillator located in vicinity of the first photodetector and the high activator density region in the first scintillator located in vicinity of the second photodetector.

In the radiological image detection apparatus, an activator density in at least one of the first and second scintillators may be changed repeatedly in at least a part f the scintillator between a high density and a low density in a radiation traveling direction.

In the radiological image detection apparatus, an activator density of the first scintillator may be changed repeatedly in a radiation traveling direction; and an activator density of the second scintillator may be kept substantially constant at an activator density, which is higher than an average of an activator density in the second scintillator, in at least a part of the second scintillator located on the second photodetector.

In the radiological image detection, an activator density in the high activator density region of the first scintillator located in vicinity of the second photodetector may be higher relatively than an activator density in the high activator density region of the first scintillator located in vicinity of the first photodetector.

In the radiological image detection apparatus, a distance between opposing surfaces of the first and second scintillators may be less than 40 μm.

In the radiological image detection apparatus, at least the second photodetector out of the first and second photodetectors may be constructed by laminating or arranging planarly photoelectric layers, each of which shows a conductivity in response to acceptance of lights, and thin film switching elements, each of which extracts electric charges from each of the photoelectric layers.

In the radiological image detection apparatus, at least the second photodetector out of the first and second photodetectors may be formed by using an organic material.

In the radiological image detection apparatus, each of the first and second scintillators may contain a columnar portion, which is formed of a group of columnar crystals in which crystals of a corresponding fluorescent material have grown into columnar shapes.

In the radiological image detection apparatus, a non-columnar portion containing non-columnar crystals may be formed on an end portion of the columnar portion in a crystal growth direction.

In the radiological image detection apparatus, a base material of the fluorescent material of one of the first and second scintillators may be CsI, and an activator thereof may be Tl.

In the radiological detection apparatus, the first and second scintillators may be constructed by fluorescent materials whose sensitivity to the radiation is different mutually.

In the radiological detection apparatus, fluorescent materials of the first and second scintillators may be different in luminance colors mutually.

In addition, it is disclosed a method of manufacturing the radiological image detection apparatus, comprising: a second photodetector forming step of forming the second photodetector on a substrate; and a substrate peeling step of peeling the substrate from the second photodetector.

In the method of manufacturing the radiological image detection apparatus, in the substrate peeling step, one of the first scintillator formed on the first photodetector and the second scintillator formed on a support may be pasted on the second photodetector formed on the substrate, and then the second photodetector may be peeled off from the substrate; and after the substrate peeling step, other of the first and second scintillators and the first scintillator may be pasted together.

The method of manufacturing the radiological image detection apparatus may further include: a supporting member removing step of forming the first scintillator on a supporting member, then pasting the first scintillator and the first photodetector together, and then removing the supporting member from the first scintillator; in which in the substrate peeling step, the second scintillator formed on the support and the second photodetector are pasted together, and then the substrate is peeled off from the second photodetector; and after the supporting member removing step and the substrate peeling step, the first scintillator and the second photodetector are pasted together.

The method of manufacturing the radiological image detection apparatus may further include: a first photodetector forming step of forming the first photodetector and the first scintillator in this order on a substrate; in which in the second photodetector forming step, the second photodetector and the second scintillator are formed in this order on the substrate; in the substrate peeling step, the supporting member is pasted on the second scintillator on an opposite side to the second photodetector, and then the substrate is peeled off from the second photodetector; and after the first photodetector forming step and the substrate peeing step, the first scintillator and the second photodetector are pasted together.

The method of manufacturing the radiological image detection apparatus may further include: a supporting member removing step of forming the first scintillator on a supporting member, then pasting the first scintillator and the first photodetector together, and then removing the supporting member from the first scintillator; in which: in the second photodetector forming step, the second photodetector and the second scintillator are formed in this order on the substrate; in the substrate peeling step, the supporting member is pasted on the second scintillator on an opposite side to the second photodetector side, and then the substrate is peeled off from the second photodetector; and after the supporting member removing step and the substrate peeling step, the first scintillator and the second photodetector are pasted together.

What is claimed is:

1. A radiological image detection apparatus comprising:
a first scintillator and a second scintillator that emit fluorescent lights in response to irradiation of radiation; and
a first photodetector and a second photodetector that detect the fluorescent lights;
wherein the first photodetector, the first scintillator, the second photodetector, and the second scintillator are arranged in order from a radiation incident side, and
a high activator density region in which an activator density is relatively higher than an average activator density in a concerned scintillator is provided to at least one of the first scintillator located in vicinity of the first photodetector and the second scintillator located in vicinity of the second photodetector.

2. The radiological image detection apparatus according to claim 1, wherein:
the second photodetector is provided by forming the second photodetector on a substrate, and peeling off the second photodetector from the substrate.

3. The radiological image detection apparatus according to claim 1, wherein:
a high activator density region in which an activator density is relatively higher than an average activator density in the first scintillator is provided to the first scintillator located in vicinity of the second photodetector.

4. The radiological image detection apparatus according to claim 3, wherein:
the high activator density region is provided to the first scintillator located in vicinity of the first photodetector; and
a low activator density region in which in which an activator density is relatively lower than an average activator density in the first scintillator is provided between the high activator density region in the first scintillator located in vicinity of the first photodetector and the high activator density region in the first scintillator located in vicinity of the second photodetector.

5. The radiological image detection apparatus according to claim 1, wherein:
an activator density in at least one of the first and second scintillators is changed repeatedly in at least a part f the scintillator between a high density and a low density in a radiation traveling direction.

6. The radiological image detection apparatus according to claim 5, wherein:
an activator density of the first scintillator is changed repeatedly in a radiation traveling direction; and
an activator density of the second scintillator is kept substantially constant at an activator density, which is higher than an average of an activator density in the second scintillator, in at least a part of the second scintillator located on the second photodetector.

7. The radiological image detection apparatus according to claim 4, wherein:
an activator density in the high activator density region of the first scintillator located in vicinity of the second photodetector is higher relatively than an activator density in the high activator density region of the first scintillator located in vicinity of the first photodetector.

8. The radiological image detection apparatus according to claim 2, wherein:
a distance between opposing surfaces of the first and second scintillators is less than 40 μm.

9. The radiological image detection apparatus according to claim 1, wherein:
at least the second photodetector out of the first and second photodetectors is constructed by laminating or arranging planarly photoelectric layers, each of which shows a conductivity in response to acceptance of lights, and thin film switching elements, each of which extracts electric charges from each of the photoelectric layers.

10. The radiological image detection apparatus according to claim 4, wherein:
at least the second photodetector out of the first and second photodetectors is formed by using an organic material.

11. The radiological image detection apparatus according to claim 1, wherein:
the first and second scintillators each contains a columnar portion, which is formed of a group of columnar crystals in which crystals of a corresponding fluorescent material have grown into columnar shapes.

12. The radiological image detection apparatus according to claim 11, wherein:
a non-columnar portion containing non-columnar crystals is formed on an end portion of the columnar portion in a crystal growth direction.

13. The radiological image detection apparatus according to claim 1, wherein:
a base material of the fluorescent material of one of the first and second scintillators is CsI, and an activator thereof is Tl.

14. The radiological detection apparatus according to claim 1, wherein:
the first and second scintillators are constructed by fluorescent materials whose sensitivity to the radiation is different mutually.

15. The radiological detection apparatus according to claim 14, wherein:
fluorescent materials of the first and second scintillators are different in luminance colors mutually.

16. A method of manufacturing the radiological image detection apparatus according to claim 2, comprising:
a second photodetector forming step of forming the second photodetector on a substrate; and
a substrate peeling step of peeling the substrate from the second photodetector.

17. The method of manufacturing the radiological image detection apparatus according to claim 16, wherein:
in the substrate peeling step, one of the first scintillator formed on the first photodetector and the second scintillator formed on a support is pasted on the second photodetector formed on the substrate, and then the second photodetector is peeled off from the substrate; and
after the substrate peeling step, other of the first and second scintillators and the first scintillator are pasted together.

18. The method of manufacturing the radiological image detection apparatus according to claim 16, further comprising:
a supporting member removing step of forming the first scintillator on a supporting member, then pasting the first scintillator and the first photodetector together, and then removing the supporting member from the first scintillator; wherein:
in the substrate peeling step, the second scintillator formed on the support and the second photodetector are pasted together, and then the substrate is peeled off from the second photodetector; and
after the supporting member removing step and the substrate peeling step, the first scintillator and the second photodetector are pasted together.

19. The method of manufacturing the radiological image detection apparatus according to claim 16, further comprising:
a first photodetector forming step of forming the first photodetector and the first scintillator in this order on a substrate; wherein:
in the second photodetector forming step, the second photodetector and the second scintillator are formed in this order on the substrate;
in the substrate peeling step, the supporting member is pasted on the second scintillator on an opposite side to the second photodetector, and then the substrate is peeled off from the second photodetector; and
after the first photodetector forming step and the substrate peeing step, the first scintillator and the second photodetector are pasted together.

20. The method of manufacturing the radiological image detection apparatus, according to claim 16, further comprising:
a supporting member removing step of forming the first scintillator on a supporting member, then pasting the first scintillator and the first photodetector together, and then removing the supporting member from the first scintillator; wherein:
in the second photodetector forming step, the second photodetector and the second scintillator are formed in this order on the substrate;
in the substrate peeling step, the supporting member is pasted on the second scintillator on an opposite side to the second photodetector side, and then the substrate is peeled off from the second photodetector; and
after the supporting member removing step and the substrate peeling step, the first scintillator and the second photodetector are pasted together.
